(19) United States
(12) Patent Application Publication
(10) Pub. No.: US 2024/0006883 A1
(43) Pub. Date: Jan. 4, 2024

(54) SYSTEMS AND METHODS FOR RESILIENT RECOVERY SERVICES FROM POWER FAILURES

(71) Applicant: Georgia Tech Research Corporation, Atlanta, GA (US)

(72) Inventors: Amir Hossen Afsharinejad, Atlanta, GA (US); Chuanyi Ji, Atlanta, GA (US); Robert Wilcox, Atlanta, GA (US)

(21) Appl. No.: 18/253,033

(22) PCT Filed: Dec. 21, 2021
(86) PCT No.: PCT/US2021/064568

§ 371 Date: May 15, 2023

Related U.S. Application Data
(60) Provisional application No. 63/128,842, filed on Dec. 21, 2020.

(51) Int. Cl. H02J 3/00; G06N 20/00; G06Q 10/0631

(52) U.S. Cl. CPC H02J 3/0012; G06N 20/00; G06Q 10/0631; H02J 2203/20

(57) ABSTRACT

A data analytics for recovery, using granular and large-scale failure data from the distribution grid. A key characteristic of the data analytics is its generalizability. The data analysis applies to a large number (169) of failure events rather than one disruption. Further, a data driven recovery scaling law characterizes how recovery speed scales with respect to the severity of weather-induced failures from moderate to extreme. The data analysis also demonstrates the promise of mitigating fundamental limitations of typical recovery through smart grid infrastructure. The data analytics generalizes from one service region in New York to another in Massachusetts. As data used are commonly available to most distribution system operators, the analytics is potentially applicable across the US and parts of the world.

### CROSS-REFERENCE TO RELATED APPLICATIONS

This application claims benefit under 35 USC § 119(e) of U.S. Provisional Patent Application No. 63/128,842 filed 21 Dec. 2020, the entirety of which is incorporated herein by reference as if set forth herein in its entirety.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### SEQUENCE LISTING

Not Applicable

### STATEMENT REGARDING PRIOR DISCLOSURES BY THE INVENTOR OR A JOINT INVENTOR

Not Applicable

### BACKGROUND OF THE DISCLOSURE

### 1. Field of the Invention

As power failures are frequently induced by severe weather in a changing climate, recovery, the service aspect of resilience, is pertinent to our society. The present invention develops data analytics for recovery, using granular and large-scale failure data from the distribution grid. A key characteristic of the data analytics is its generalizability. The data analysis applies to a large number (169) of failure events rather than one disruption. Further, a data driven recovery scaling law characterizes how recovery speed scales with respect to the severity of weather-induced failures from moderate to extreme. The data analysis also demonstrates the promise of mitigating fundamental limitations of typical recovery through smart grid infrastructure. The data analytics generalizes from one service region in New York to another in Massachusetts. As data used are commonly available to most distribution system operators, the analytics is potentially applicable across the US and parts of the world.

### 2. Description of Related Art

Natural disasters happen with increasing intensity in the US and worldwide. Resilient infrastructure and services are thus crucial for our society. This problem, while relevant to most infrastructures supporting our society, is particularly acute to the energy grid. Indeed, large-scale power failures have been induced by nearly all natural disasters from hurricanes to winter storms. Millions of people have lost electricity supplies for extended durations. Operational distribution grid (i.e., the final stage of energy infrastructure) is particularly vulnerable, representing 90% of failures. Resilience of the distribution grid is thus called for both the infrastructure and services, where the former is to reduce failures, natural or man-made, and the latter is to recover rapidly upon disruptions.

In particular, issues involved with resilient recovery services from power failures include:

How resilient our energy infrastructure and services really are in face of weather events of different intensity?

How to measure resilience of the distribution grid that captures both the dynamic spatiotemporal nature of failures and recovery as well as the cost on individual customers?

How can such a resilience metric serve to understand the heterogeneity of impact on different communities and people, especially more vulnerable ones?

Service resilience in particular, is to minimize the impact of failures on customers, with respect to increasing severity of failure events and different weather conditions. A fundamental problem is whether and how recovery guided by commonly-adopted policies is resilient to a wide range of disruptive events from moderate to severe and extreme. Recovery from large-scale power failures exhibits a typical setting that involves service providers, customers and government policies which guide the restoration. A well-adopted policy by emergency responders in general is to help as many people as fast as possible under resource constraints. Distribution grid operators implement this guiding principle as their triage, i.e., to prioritize the restoration (sequence) on large failures that affect a high number of customers.

There have been controversies on the services guided by such recovery policy: (a) adopted by providers and disaster responders as a gold standard, but often complained by customers for slow recovery from disruptions and (b) demonstrated as suboptimal by recent work on algorithm design. In particular, the data analysis on Superstorm Sandy and Hurricane Maria shows that small failures, which are not prioritized, experienced long interruption durations. The long interruption time is found to be particularly damaging to customers. The policy itself, however, has been largely sidelined by the prior work. Further, large-scale power failures induced by weather disruptions happen with an increasing severity. Field studies on the resilience of recovery services, i.e., using data from the operational grid and customers, are lacking across a wide range of failure events induced by weather disruptions.

As a result, there does not exist an established benchmark measuring the performance of recovery guided by underlying policies. Knowledge is much needed on (a) how the recovery services perform across failure events of different intensity in the first place, (b) capabilities and fundamental limitations of recovery guided by well adopted policies seen by the field data and (c) whether we can mitigate the fundamental limitations through the future energy infrastructure.

A key challenge for such a field study originates from lack of granular data at a large scale. This has taken two forms: a primary focus on individual extreme events and spatial temporal aggregation. First, failure event data are unevenly adopted across a range of severity; the failure events that have been studied are usually those severe enough to make the news headlines. Using individual failure events, however, does not allow a systematic study on whether recovery services are resilient, i.e., maintain a desirable performance despite the increasing severity of failure events. Second, most work on historic power failures and recovery has used data aggregated over townships or service regions and hours since the granular measurements are privately owned and thus difficult to obtain. Advanced data collection and analysis are emerging from smart meter infrastructure and micro PMUs (Phasor Measurement Units). Unfortunately, such advanced data collection is not widely deployed due to high costs.

### BRIEF SUMMARY OF THE INVENTION

Severe weather events are occurring in a changing climate in the US and worldwide affecting millions of customers for long amount of time. Service resilience as the ability of a service provider to minimize the impact of failures on customers is thus of crucial importance. Using large-scale data analytics illustrates the effectiveness and limitations of service resilience in the face of weather events with different intensity from moderate to severe and extreme. A dynamic metric is developed to measure resilience of the system at any instance in time and the location of choice. This metric enables studying the distribution grid under variety of impacts providing important insight on how customers are affected. Additionally, how the resilience metric is defined allows for the development of a randomization inference framework to test for the statistical dependence between customer vulnerability and the power failures resulting from severe weather events.

First, granular large-scale data are introduced spanning across 2011-2019 in New York and Massachusetts. Data processing methodologies are provided on how weather events are extracted from data with moderate, severe and extreme severity resulting in a total of 169 events. Next, how distribution grid and customers are impacted across these weather events from moderate intensity to extreme is studied. This analyses provides insight on how the grid is affected in the first place, which serves as building block for service resilience analysis. Additionally, the definition of an infrastructure vulnerability and failure scaling law is extended to show how this vulnerability is inherent in grid design and not just the result of a high intensity weather event.

Next, moderate, severe and extreme events are used to show the effectiveness and limitations of service resilience and recovery performance. In particular, unsupervised learning along with the large-scale data are used to identify regions showing strong dependence between failure characteristics and recovery speed. The four resulting cluster regions are used in a newly developed recovery scaling law that shows how customers experience recovery across weather events with different intensity. Then, the analysis is extended to Massachusetts to show the challenges and opportunities of such extension. Finally, the answer to the question of how and to what extent infrastructure enhancement can potentially help expedite recovery is presented by focusing on failures with long durations that affect large number of customers. In particular, using simulations, the performance improvement obtainable if service providers are able to give priority to failures with the most impact (long duration and large number of customers affected) is quantified.

Next, a dynamic resilience metric is formulated by defining failure, recovery and cost processes. This metric enables measuring the different cost variables of individual customers at their specific time and location. Thus, this approach serves as a mathematical model that captures the dynamics of storm-caused power failures and recoveries and accounts for variability in the vulnerability of consumers and communities to power failures. Then, using a resilience metric in social settings, a randomization inference framework is proposed. This framework examines the statistical relationship between the spatiotemporal distribution of failure and recovery and the variability in social vulnerability across individuals and communities. The present invention gives service providers a toolbox to analyze different regions of their service territory in terms of socioeconomic costs up to granularity of communities to identify possible vulnerabilities and take action.

A large-scale and granular data set from 2011 to 2019 across New York and Massachusetts was utilized to define failure events of different intensity: moderate, severe and extreme. Such data processing, enables studying the system under variety of external stress levels resulting from weather conditions which is essential in understanding the behavior and limitations of the system. Then, how these failures impact the grid in terms of customers affected and disrupted devices is examined. The results show similar distributional sampling on a high level across weather events of different intensity, while significant differences were also highlighted on the edge of the network such as ˜20% different in one customer's failures between moderate and extreme events.

A failure scaling law is used to study the inherent infrastructure vulnerability. The scaling law is used and is extended to factor in weather and failure category variables. Then, failure scaling laws are obtained using the extended formulation for moderate, severe and extreme events that showed a rough scaling of 20% 90% exists regardless of event severity. In other words, only 20% of failures account for 90% of total customers affected, meaning relatively small number of failures can result in significant impact on customers. This behavior confirms that infrastructural vulnerability is not just caused by major weather events, it only gets exacerbated which calls for proactive measures in improving the resilience of the grid. The analyses and results are obtainable due to granularity of the data. Aggregated data and variables do not allow reproduction of the results which highlights one of the many benefits of granular data.

Further analysis including additional weather, geolocations and failure category variables is needed to deepen understanding on how the physical infrastructure is impacted by failures resulting from weather events with different severity. Establishing such insight for different geolocations can significantly help service providers plan ahead of time for weather events. The current results, however, play a critical role in understanding the failures' impacts on the grid and also serve as a building block for service resilience studies.

This work performs a large-scale field study on the resilience of recovery services from power failures, using granular data at the operational distribution grid. Our data span two service regions in two US states on disruptive weather events of different severity in the past nine years. Guided by unsupervised learning from non-stationary data, our analysis has drawn new knowledge on recovery services governed by a widely adopted policy.

Further analysis finds that the behavior of restoration services follows a recovery scaling law. The recovery reinstalls services for the majority (˜90%) of affected users at the cost of a small fraction (˜10%) of the total interruption time. Such recovery scaling persists across failure events of different severity and different types of weather disruptions. This shows the capability of services guided by prioritization policy and thus a desirable property of resilience.

The recovery behavior is observed to show prioritization favoring large failures. The prioritized recovery degrades with the intensity of disruptive events. There is a significant (˜30%) increase of the large failures that cannot be prioritized, resulting in 47 times longer customer interruption time from the moderate to extreme failure events. Further, the prioritized recovery does not optimize restoration of small failures. In fact, small failures dominate delayed recovery during an entire evolution of an extreme event. These findings show that the typical services governed by the prioritized recovery policy is at the cost of the disparity; and the cost is significant when failure events become severe and extreme. Hence, the analysis shows a fundamental limitation of recovery under the prioritization policy, where rapid restoration does not sustain to severe and extreme failure events.

To understand whether it is possible to mitigate the fundamental limitation, a paradigm shift was explored on infrastructure enhancement, i.e., using distributed generation and storage to expedite the recovery. Such an approach scales well: expediting restoration of a small fraction (e.g., ˜7%) of the large failures in the non-prioritized category can reverse the degraded recovery from the moderate to extreme events. Thus, the recovery scaling provides not only new insights but also guidelines on potential enhancements of recovery services. While this preliminary study is promising, extensive research is needed on the benefit of the smart grid to resilient recovery services.

The fundamental limitation remains challenging for recovery of the small failures. There are a large number of small failures that affect a moderate number of customers. Thus, the recovery and failure scaling laws do not offer guidance for restoring the small failures. Hence, a combined enhancement on the infrastructure close to customers and recovery strategies can be necessary for reducing the interruption time to all users.

The data is commonly available to most distribution grid operators in the US and parts of the world. Thus, this study demonstrates that energy service providers have the ability to adopt data science, that is, to turn their own data into new knowledge, to benchmark and improve recovery as well as infrastructure enhancement.

This also shows significant challenges for scaling up data analytics even from one US state to its neighbor. Service regions are often governed by different polices as shown by the case of disaster declaration. Service regions also have different geographical characteristics and possibly grid structure. Hence, data analytics for resilient energy services requires active participation of both service providers and policy makers, to contribute data, expertise and willingness to adapt. This study hopes to encourage such an endeavor.

Existing standard evaluation metrics for power grids emphasize the speed of grid recovery and uniformly restoring service to as many customers as fast as possible. Therefore, the substantial heterogeneity in user vulnerability to severe weather induced failures is ignored in performance evaluations. However, a dynamic spatiotemporal resilience metric is devised that takes into account the varying impact on individual customers instead of treating them all uniformly. This framework enables service providers and researchers to study any level of cost granularity in time and space from communities to individual customers. The cost variable in the derivation can also target any type of impact such as business, economic and social costs depending on the availability of the data. It was also shown how special cases of our derivation can provide flexibility focus on different characteristics of the grid namely: CMI, failures and durations. The current resilience metric is extended to study the socioeconomic impact on customers for Hurricane Michael in 2018 that plays a critical role in determining how service provider performance affects wellbeing of customers of different vulnerability.

Existing research on and standard metrics for evaluating power grid resilience during major storms focus on the performance of energy infrastructure to a greater extent than the distributional impact of power failures on customers and communities. However, recent research indicates that the overall speed of power grid recovery and the differential vulnerability of consumers and communities to power failures must be considered together in order to accurately gauge the disruptive effects of storm-related power failures. Our work develops an integrated approach that brings the resilience of the grid and community characteristics together. We develop a mathematical model that incorporates variability in the vulnerability of consumers and communities into prior work examining power failures and recoveries.

This results in a dynamic resilience measure that brings together the incidence of power failures, the speed of recovery, and the vulnerability of customers. Further, we develop a hypothesis testing framework for examining the relationship between the spatiotemporal distribution of failure and recovery on the one hand and variability in vulnerability across individuals and communities on the other. We then apply our method to publicly available data on failure and recovery of customers from Alabama, Georgia and Florida for Hurricane Michael, a Category 5 storm which hit the Southeast in October 2018. We conclude that the impact of Hurricane Michael was biased towards more vulnerable communities in Georgia even after conditioning on the affected communities. In contrast, we do not observe significant statistical dependence in Alabama and Florida.

However, our study faces a number of limitations that we seek to address in future research, of which many are data-driven. The inability to connect individual customers to failed devices requires that we aggregate the impact on county level and not be able to validate our model for conditioning dynamically on the storm path. Further, the lack of customer-level data requires that we rely on Census tract-level or county-level summaries of social vulnerability, which could obscure important within-region customer variation. Moreover, we only apply our methodology to a single storm and three contiguous states. With more detailed data, we would be able, for example, to explore a wider variety of mechanisms connecting failure intensity and customer vulnerability.

By developing a statistical methodology that integrates data from the grid with data about consumers, this study is an important step in the effort to generate new knowledge to help utilities and policymakers better service communities in need. Following major storms, careful analysis of both the speed of recovery and the distributional impact of the storm offers the potential to inform utilities and policymakers about how to allocate investments in grid robustness and how to update recovery routines to minimize the future impact of storm-caused power failures.

We emphasize, however, that there are a number of mechanisms that could explain why more economically or socially vulnerable customers would also experience longer power outages, many of which are largely out of the control of a power utility. However, we believe that our method—used in tandem with the engineering measures of grid resilience—creates the potential for utilities and policymakers to build new insights about the distributional impact of severe storms and to use this knowledge to inform decisions about grid robustness and storm recovery routines. A successful response to a damaging storm involves both minimizing the time without power for an average customer and ensuring that vulnerable customers and communities are protected from the storm's effects.

According to an exemplary embodiment, the present invention comprises a method of prioritizing recovery from power failures across a utility service from among different failure severity characterizations of the power failures by unsupervised learning of non-stationary data related to prior failure events.

The method can further comprise developing a recovery scaling law for service resilience based upon analyses of the data related to prior failure events.

The failure severity characterizations can be discrete categories based upon a number of number of customers affected by each failure event.

At least a portion of power failures having a smaller failure severity characterization than larger failure severity characterizations can be prioritized for recovery prior to recovery of the larger failure severity characterizations.

According to an exemplary embodiment, the present invention comprises a method basing resilient recovery services from large-scale data analytics on prior failure events of different severity comprising systematically studying prior recovery services under different severities of failure impact, developing a recovery scaling law through unsupervised learning of the large-scale data, and improving the performance of resilient recovery services from power failures based upon the studying and developing.

Improving can comprise enhancing recovery of a portion of large failures through distributed generation and storage.

At least a portion of the failure events can be induced by weather disruptions.

The large-scale data can comprise non-stationary data.

The studying can find that under widely adopted prioritization policies favoring larger failures, recovery exhibits a scaling property where a majority of customers recovers in a small fraction of total downtime.

The majority of customers can be about 90% of customers.

The studying can further find that recovery degrades with the severity of failure events.

Larger failure events that cannot recover rapidly can increase by 30% from lesser, moderate to extreme failure events.

Prolonged small failures can dominate the entire recovery processes.

According to an exemplary embodiment, the present invention comprises a method of prioritizing the recovery of power failure events, the power failure events categorized by severity based upon the number of customers affected by each power failure event, using data analytics for recovery priorities, using granular and large-scale failure data from the distribution grid comprising developing a data driven recovery scaling law that characterizes how recovery speed scales with respect to the severity of power failure events.

According to an exemplary embodiment, the present invention comprises a method of basing smart grid infrastructure off of the inventive prioritizing.

According to an exemplary embodiment, the present invention comprises a method to compare/analyze the effectiveness of enhancement procedures or investments to the prioritization of recovery of power failure events comprising testing recovery performance of a first state of a grid, and testing recovery performance of a second state of a grid, wherein the second state of the grid comprises grid enhancements or adoption of additional distributed energy resources over the first state of the grid.

The grid enhancements or adoption of additional distributed energy resources can be a result of using a method of prioritizing the recovery of power failure events, the power failure events categorized by severity based upon the number of customers affected by each power failure event, using data analytics for recovery priorities, using granular and large-scale failure data from the distribution grid comprising developing a data driven recovery scaling law that characterizes how recovery speed scales with respect to the severity of power failure events

According to an exemplary embodiment, the present invention comprises a method of using a data-driven tool to make regulatory decisions, the data-driven tool comprising a data driven recovery scaling law that characterizes how recovery speed scales with respect to severity of power failure events.

These and other objects, features and advantages of the present invention will become more apparent upon reading the following specification in conjunction with the accompanying drawing figures.

### BRIEF DESCRIPTION OF THE DRAWINGS

The accompanying Figures, which are incorporated in and constitute a part of this specification, illustrate several aspects described below.

FIGS. 1A, 1B are graphs of the distribution of failure size over five logarithmically divided categories for (FIG. 1A) extreme and moderate events, and (FIG. 1B) severe and moderate events in New York. The Y-axis is the percentage of failures and the X-axis is logarithmic categories of failure size S₁, . . . , S₅. The distributions are obtained as an average over all weather events in a severity group, and one standard deviation for extreme, severe and moderate events for S₁ to S₅ are (2%, 1.9%, 2.8%, 1.8%, 3.3%), (4.2%, 4.2%, 6.8%, 4.3%, 11.1%) and (3.2%, 3.3%, 5.8%, 3.7%, 4.2%), respectively.

FIGS. 2A, 2B and 2C are graphs of the distribution of protective devices activated for (FIG. 2A) extreme, (FIG. 2B) severe and (FIG. 2C) moderate weather events in New York. The Y-axis is the percentage of failures and the X-axis is logarithmically divided categories of failure size S₁, . . . , S₅. The distributions are obtained as an average over all weather events in a severity group, and error bars are shown in red corresponding to one standard deviation.

FIGS. 3A, 3B and 3C are graphs of the failure scaling law for weather events in New York. The Y-axis (Customers %) is the empirical probability \tilde{P}_{c}(x; H_{w}, Gⱼ) as the cumulative percentage of affected customers and the X-axis (Failures %) is the empirical probability \tilde{P}_{f}(x; H_{w}, Gⱼ) that a disruption affected more than x customers for (FIG. 3A) extreme, (FIG. 3B) severe and (FIG. 3C) moderate events in New York. The curve is obtained over failure events in New York, and shaded regions are one standard deviation. The line transition is for large (>100 affected customers) and small (<100 impacted users) failures, respectively.

FIG. 4 is a graph of an overview of failure events: 169 failure events from the moderate to severe and extreme. The horizontal axis shows event occurrence time from February 2011 to January 2019. The vertical axis is on the longest recovery durations in hours, where 99% of the failures recovered from each event. The radius of a marker represents the number of failures of a disruptive event from 100 to 6052 failures. The lighter three grey-scale markers represent moderate, severe and extreme events from New York, respectively. The darkest marker is for extreme events in Massachusetts. Thick and thin circles are for winter and non-winter storms respectively.

FIGS. 5A-5F are graphs of statistical dependence between the recovery speed and failure size is averaged over the failure events in New York for (FIG. 5A) extreme winter, (FIG. 5B) extreme non-winter, (FIG. 5C) severe winter, (FIG. 5D) severe non-winter, (FIG. 5E) moderate winter and (FIG. 5F) moderate non-winter disruptions, respectively. The horizontal axis shows the failure size and the vertical axis represents the recovery speed from 1 (the fastest) to 0 (the slowest). Gray scale bar shows the values of statistical dependence. The boundaries highlight the two regions: (i) Prioritized large failures at the upper left and (ii) Prolonged small failures at the lower right. The average value of statistical dependence within the boundaries exceeds 5% of the maximum value.

FIGS. 6A-6D include graphs of recovery scaling coupled with failure scaling for New York. FIG. 6A shows the failure scaling law. The X-axis (Failure %) is the empirical probability \tilde{P}(x; s, w) that a disruption affected more than x customers. The Y-axis (Customer %) is \tilde{P}_{c}(x; [s, w]). The curve is obtained over failure events in New York, and shaded regions are one standard deviation. The grey scale are for large (>100 affected customers) and small (<100 impacted users) 2-10 failures, respectively. FIG. 6B shows the recovery scaling law for moderate, severe and extreme failure events. The Y-axis (Customer %) is \tilde{P}_{c}(x; [s, w]) and the Z-axis (Duration %) is \tilde{P}ᵣ(d; [s, w]), for prioritized-large, non-prioritized-large, remaining-small, and prolonged-small failures. The numbers on both plots separated by “/” present non-winter/winter weather events. The curves, line-markers and the bold numbers before “/” are for the non-winter events. FIGS. 6C, 6D are histograms on the types of disrupted devices for extreme non-winter (FIG. 6C) and winter (FIG. 6D) events at New York over different failure sizes.

FIGS. 7A-7D illustrate a temporal evolution of the four failure categories during (FIG. 7A) extreme non-winter events in New York, (FIG. 7B) extreme winter events in New York, (FIG. 7C) extreme non-winter events in Massachusetts and (FIG. 7D) extreme winter events in Massachusetts. The vertical axis is the number of failures waiting to recover at a given time instance, for the PL: prioritized-large, nPL: non-prioritized large, RS: remaining small and PS: prolonged small failures. The horizontal axis is time instance past start of the event. Each curve is for one extreme failure event.

FIGS. 8A, 8B are geolocation of (FIG. 8A) large and (FIG. 8B) prolonged small failures in extreme events of New York. The radius of the circles correspond to downtime durations from 0 to 170 hours. The darker markers in (FIG. 8A) correspond to the prioritized large failures. The lighter markers in (FIG. 8A) show the non-prioritized large failures. The lightest markers in (FIG. 8B) represent the prolonged small failures in the extreme events.

FIGS. 9A, 9B and 9C are inference diagrams for (FIG. 9A) three extreme winter and (FIG. 9B) three extreme nonwinter events in Massachusetts. The X-axis shows failure sizes and the Y-axis represents the recovery speed from 1 (the fastest speed) to 0 (the slowest speed). Grey scale bar shows the value of statistical dependence with a maximum value of 5%. The boundaries highlight the regions of prioritized large and prolonged small recovery. (FIG. 9C) Recovery scaling law for extreme events in Massachusetts. The X-axis represents the empirical probability \tilde{P}_{c}(x; w) as the cumulative percentage of customers being affected. The Y-axis shows the empirical probability \tilde{P}ᵣ(d; w) as the cumulative percentage of the downtime durations experienced by those affected customers. Various lines correspond to the prioritized large, non-prioritized large, remaining small and prolonged small, respectively. The numbers on before and after “/” present the two types of corresponding weather events: non-winter and winter, respectively.

FIGS. 10A-10D illustrate enhancement of recovery for extreme failure events. Percentage of random improvement on the affected customers (left vertical axis) and customer interruption time (right vertical axis) for (FIG. 10A) New York and (FIG. 10B) Massachusetts are plotted. The horizontal axis: percentage of large failures that are drawn from the non-prioritized category. (FIG. 10C) Recovery scaling law after 2% random enhancement for extreme events in New York. (FIG. 10D) Recovery scaling law similar to that of moderate events after 7% randomly enhancement of extreme events in New York. The horizontal axis of FIGS. 10C, 10D is the cumulative percentage of customers being affected. The vertical axis is the cumulative percentage of the downtime durations by the affected customers. Shades correspond to the prioritized large, non-prioritized large, remaining small and prolonged small failures, respectively.

FIGS. 11A, 11B and 11C are overlapping SVI histograms over bins of width 0.1 that are plotted for counties of (FIG. 11A) Georgia, (FIG. 11B) Alabama and (FIG. 11C) Florida weighted by maximum number of customers served. The darker histograms show the SVI distribution over all counties in each state, while the lighter histograms represent the SVI distribution of counties affected by Hurricane Michael weather event. Both histograms are weighted by maximum number of customers served.

FIGS. 12A, 12B and 12C illustrate the vulnerability-weighted customer resilience of communities is shown in (FIG. 12A) Georgia, (FIG. 12B) Alabama and (FIG. 12C) Florida for the data-driven estimate and null hypothesis. The dashed lines are the 90% confidence intervals of the average null hypothesis (solid curve). The null hypothesis here is defined over all counties in each state.

FIGS. 13A, 13B and 13C illustrate the vulnerability-weighted customer resilience of communities is shown in (FIG. 13A) Georgia, (FIG. 13B) Alabama and (FIG. 13C) Florida for the data-driven estimate and null hypothesis. The dashed lines are the 90% confidence intervals of the average null hypothesis (solid curve). The null hypothesis here is defined over counties affected by Hurricane Michael in each state.

FIGS. 14A, 14B show the proportions of time that vulnerability weighted resilience Res(t) falls outside the confidence region defined by α, i.e., π(t₀, t₁, 0.10) and critical values (π*(t₀, t₁, 0.10,0.10) are plotted for (FIG. 14A) scenario I and (FIG. 14B) scenario II of Georgia, Florida and Alabama for the entire storm (left), failure (middle) and recovery phases (right).

FIGS. 15A, 15B show failure and recovery processes from an extreme failure event occurred in April 2018. (FIG. 15A): Recovery durations as a function of failure occurrence time. The markers represent failures that occurred during stages 1 and 2, respectively. Stage 1 is when failure process overwhelms recovery and stage 2 is when recovery rate exceeds failure rate, thus recovery process dominates. The vertical line corresponds to the point in time where the number of failures waiting for repair reaches its peak value. (FIG. 15B): Failure rate, recovery rate and number of pending repairs as a function of time, where these three quantities are normalized by their respective maximum values.

FIGS. 16A, 16B and 16C illustrate the statistical dependence between the recovery speed and joint distribution of grid structure and failure size is averaged over the failure events for (FIG. 16A) extreme, (FIG. 16B) severe and (FIG. 16C) moderate events. The X-axis (top) shows the abbreviated type of disrupted devices within each failure size category. B: station breakers, R: reclosers, S: solid discs, F: fused discs and T stands for transformers. The X-axis (bottom) shows failure size and the Y-axis represents the recovery speed from 1 (the fastest) to 0 (the slowest). Shade bar shows the values of statistical dependence.

### DETAILED DESCRIPTION OF THE INVENTION

Although preferred exemplary embodiments of the disclosure are explained in detail, it is to be understood that other exemplary embodiments are contemplated. Accordingly, it is not intended that the disclosure is limited in its scope to the details of construction and arrangement of components set forth in the following description or illustrated in the drawings. The disclosure is capable of other exemplary embodiments and of being practiced or carried out in various ways. Also, in describing the preferred exemplary embodiments, specific terminology will be resorted to for the sake of clarity.

As used in the specification and the appended claims, the singular forms “a,” “an” and “the” include plural referents unless the context clearly dictates otherwise.

Also, in describing the preferred exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges can be expressed herein as from “about” or “approximately” one particular value and/or to “about” or “approximately” another particular value. When such a range is expressed, another exemplary embodiment includes from the one particular value and/or to the other particular value.

Using “comprising” or “including” or like terms means that at least the named compound, element, particle, or method step is present in the composition or article or method, but does not exclude the presence of other compounds, materials, particles, method steps, even if the other such compounds, material, particles, method steps have the same function as what is named.

Mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

The foundation of the present invention is providing methodologies on how to use large-scale data analytics to measure and analyze resilience of power distribution grids and the impact on customers to help service providers and policy makers make decision on improving the gird and well-being of customers. Our large-scale data during 2011-2019 across New York and Massachusetts are introduced. Using spatial and temporal data processing, three severities of events: moderate, severe and extreme are defined. The impact of the failures on customers and physical infrastructure of the grid is then analyzed in the resulting weather events. The results show how the distribution such impact changes as the intensity of the events increases. Finally, extending the prior work, a generalized failure scaling law is obtained across moderate to extreme weather events which shows that on average, 20% of the failures affect around 90% of total customers regardless of event severity. This result shows infrastructural vulnerability, defined as small and local failures affecting large number of customers, is not just caused by major weather events, it only gets exacerbated. Hence, lower intensity of events can serve studying this vulnerability more comprehensively.

Next, a large-scale field study is performed on the resilience of recovery services from power failures, using our granular non-stationary data and unsupervised learning methodology. Our analysis shows that restoration services follows a recovery scaling law where (˜90%) of affected users are recovered at the cost of a small fraction (˜10%) of the total interruption time. In other words, recovery efforts mainly respond to infrastructure vulnerability (shown with failure scaling law) to recover as many customers in the shortest amount of time; i.e. prioritizing large failures. However, we also show that prioritization of large failures significantly deteriorates by ˜30% as intensity of failure events increase from moderate to extreme. Next, we use a simulation based infrastructure enhancement scheme to understand whether it is possible to mitigate the fundamental limitation of recovery services. The results show that expediting restoration of a small fraction (e.g., ˜7%) of non-prioritized large failures can reverse the degraded recovery from the moderate to extreme events. Finally, our work shows the challenges and promises of the critical problem of scaling up data analytics from one state to another as service regions are often governed by different polices and have different geographical characteristics.

Next, we formulate the spatiotemporal processes governing failures, recovery and cost in power distribution grids. Then, using the cost process, a dynamic spatial-temporal resilience metric is developed that takes into account the varying impact on individual customers. This is in contrast to treating the customers all uniformly which is the common approach among service providers and policy makers. Our resilience metric provides the flexibility to study any cost measure for customers down to desired granularity in time and space.

Next, we extend our dynamic resilience metric to a hypothesis testing framework to examine how the spatial-temporal distribution of failure and recovery correlates with variability in social vulnerability across individuals and communities. We then apply our method to publicly available on failure and recovery of customers from Alabama, Georgia and Florida for Hurricane Michael, a Category 5 storm which hit the Southeast in October 2018. To capture social vulnerability of customers, CDC's social vulnerability index (SVI) on county level is used as the cost variable. Our results illustrate how integrating data from the grid and consumers can generate new knowledge for service providers and policy makers to identify more vulnerable communities and better serve consumers in need.

The present invention includes a large-scale field study from operation distribution grid that evaluates recovery services from power failures. A data science approach is taken for the field study. First, large-scale data is gathered on recovery from power failures at two service regions in New York and Massachusetts over the nine years 2011-2019 across multiple weather events. The data are granular in geolocation and time, making it possible to relate restoration of the grid to impacted customers at the micro-level. Second, how failures impact the infrastructure are studied through different severity of the weather events. The resulting understanding is a building block of structuring the framework for service resilience. Next, a mathematical framework is developed to formulate the recovery study through unsupervised learning, an AI approach that begins to show potential in the energy domain. The analytics algorithm learns from the non-stationary behaviors of recovery over the failure events of different severity. The data analysis results in previously unknown knowledge on recovery, including capability, fundamental limitation, and potential for improvement.

Next, the invention focuses on how communities of service users are affected by failures in power grid and the existing heterogeneity in such impact. Research on power grid resilience during severe weather events focuses on the performance of energy infrastructure to a greater extent than on how customers are affected. However, recent research on the heterogeneous impact of power failures on customers suggests that evaluating the costs of storm-caused power failures requires measuring both the overall speed of recovery and the differential vulnerability of consumers and communities. Customer vulnerability to power outages is highly skewed and depends on whether the customer is residential or commercial and also on their ability to withstand an extended period without power supplied from the grid. Mobility-constrained residential customers and those reliant on the grid for necessary medical supplies, for example, find outages more disruptive than customers who can more easily leave the area during a hurricane warning. Restaurants, mines, factories, and construction firms also tend to bear larger costs of prolonged outages than other businesses due to outsized costs associated with stopping and starting production and the substantial energy requirements for daily operations.

Standard metrics for evaluating the performance of electrical utilities during storms similarly prioritize the overall speed of recovery. As a result, during major storms, utilities collect granular information on the number of poles broken, trees on power lines, miles of wire that require repair, number of devices impacted, and aggregate counts of customers without power in order to inform their recovery priorities. Except for prioritizing critical infrastructure, differential characteristics of individual customers or communities are typically not considered in real-time decisions about grid recovery.

To find an answer to such a challenging problem, first resilience as a dynamic spatiotemporal metric to study the impact of failures and recovery on customers' needs to be defined. For this purpose, a model is developed that integrates non-stationary failure and recovery processes and add impact variables from the bottom up. The resulting model is dynamic in nature, starting from individual components, incorporating structures of power distribution and most importantly connecting the physical grid to customers. The resulting non-stationary resilience measures the impact of one metric dependent on time, geolocation, and system location. This integrated approach brings customer and community characteristics together with the existing tools for evaluating grid resilience and enables us to focus more on the distributional impact of power failures on customers and communities rather than just the performance of energy infrastructure. Then, a randomization inference framework is developed for examining the statistical relationship between the spatiotemporal distribution of failure and recovery and the variability in vulnerability across individuals and communities.

### Impact of Failures on Distribution Power Grid

Introduction

A severe weather event, when occurs, often results in a large number of power failures at the distribution grid, leaving millions of customers without power. For example, hurricane Sandy in 2012 knocked out power to more than 8.66 million customers across the northeastern states of the US. Studying the resulting disruptions thus provides the first step towards a more resilient infrastructure: We need to know, in the first place, the impact of failures on service providers and customers as well as their ability to withstand it.

A considerable body of work has focused on predicting the impact of severe weather events in terms of number of failures and their spatial distribution, customers affected and the probability for components to fail. Methods used are categorized into two groups. The first is on statistical learning approaches divided into parametric, non-parametric and semi-parametric methods. The second group is on fragility based methods that relate the effects of different weather variables on failure probability of components. These provide insights and promises on the ability of predicting the impact of a severe weather event on power grids. However, as aggregated data are used for prediction, the predicted quantities do not have sufficiently high accuracies, leaving room for improvement in this area.

Weather models have also been proposed to characterize severe weather and the impact on the power grid. There, the impact is characterized by variables such as failure rate and probabilities of lines, towers and components failing. A two-state Markov chain is a widely used weather model, where the states are defined for normal and adverse weather. A three-state model, as an extension, adds a Major Adverse weather state to the previous model. These models are too simple to capture the complexity and fluctuations of the weather. As such, a multi-state model has been introduced. However, the performance of the multi-state model is only tested on a two line parallel redundant circuit. It should be noted that weather conditions are usually assumed to remain constant during an event. And different regions are assumed to experience the same conditions. To capture the weather conditions more realistically, the power grid territories are divided into weather regions. The weather is assumed to be the same within each region, but varies across different regions. This approach implies that weather changes abruptly at the borders of the regions, and thus comes short of representing the realistic dynamicity of the weather.

Failure size distribution is introduced to measure the impact of weather events. Others have studied such a quantity using publicly available data on power failures in the US between years 2002-2017. The events used in this study either affected more than 50,000 customers or resulted in a power shed of more than 300 MW. The estimated exponent of power law distribution from the data is shown to vary significantly during different hours of the day and months of the year. Such variation holds for even small sub-regions of the US. The result of this work implies that aggregation of quantities, in particular failure size, over time and region, might result in inaccuracies in modeling the impact of weather events.

One additional aspect of the impact is about how outages cascade through the power grid network. As well-studied in the past, cascading is not necessarily limited to severe weather events and can happen under different circumstances. Nevertheless, the effect of weather conditions on cascading failures has been studied. Weather-related cascades, although only occur as a minority, are shown to exhibit significantly increased propagation and outage rate compared to non-weather-related cascades. A result is obtained by statistically analyzing 14 years of transmission line outage data from a North American power utility.

The economic impact of weather induced power failures, although important, has been relatively less studied. Prior work uses regression to project long-run economic cost of power interruptions in face of different types of future severe weather events. In particular, the cumulative customer costs by the end of century are estimated with or without aggressive undergrounding and increased spending. Although promising, the approach relies on the data aggregated annually for estimating the future costs of power failures.

With the above background in mind, one goal of the present invention is to introduce a large-scale granular dataset and how events of different severity from moderate to severe and extreme are extracted from it. Then, profile of the resulting failures in weather events of different severities are compared to provide insight on their impact on the grid. This comparison can serve as a critical first step to help service providers understand the commonalities and differences in failures' impact when recovery is happening and also to make the grid more resilient.

Finally, the existence of infrastructural vulnerability across different severities of events is tested. To elaborate, a majority of the failures occurred during weather events at the distribution grid are due to local causes such as damaged poles and trees, fallen debris and flooding. These failures usually do not cascade as they follow radial distribution designs, meaning they do not result in failures of other components of the system. However, a damaged component can result in devices downstream to lose power without being damaged. Infrastructural vulnerability is thus defined as whether the impact of a local failure remains local; i.e., it only affects small number of customers. It has been shown that a 20-80 scaling behavior for both Hurricane Sandy in 2012 and daily operations data in the same year across service providers in New York. This scaling means 20% of failures account for 80% of total customers affected. The similarity of the scaling between daily operations and Hurricane Sandy indicates the weather event only exacerbated the currently vulnerable infrastructure. Here, we extend the proposed scaling law to include additional variables and cover all of the weather events from moderate to extreme to show the level of infrastructure vulnerability. The existence of such vulnerability calls for improvements not only to recovery after the fact, but also to grid structure and components.

Data

Granular data is collected on failure and recovery at the service territories in New York and Massachusetts during 2011-2019.

TABLE 1

| State | Severity | Events | Weather | Failures | Customers | Duration |
|---|---|---|---|---|---|---|
| New York | Extreme | 6 | 3 winter, | 11,880 | 1,661,584 | 244,618 |
| | | | 3 non-winter | | | |
| | Severe | 54 | 23 winter, | 19,831 | 3,438,862 | 198,505 |
| | | | 31 non-winter | | | |
| | Moderate | 103 | 24 winter, | 20,133 | 5,392,693 | 1,356 |
| | | | 79 non-winter | | | |
| Massachusetts | Extreme | 6 | 3 winter | 21,900 | 1,644,237 | 808,221 |
| | | | 3 non-winter | | | |

TABLE 1 is a summary of the data sets from New York and Massachusetts. Severity: Moderate, severe and extreme failure events. Events: number of failure events of given severity. Weather: Type of weather disruptions that induce failures. Failures: number of failures in the events of given severity. Customers: number of customers affected by the failure events. Duration: total hours of downtime durations experienced by the customers.

Both New York and Massachusetts data sets are on the same variables. Each data sample contains detailed information regarding failures and recoveries: failure occurrence and recovery time in minutes, the number of affected customers per failure, the device type, geo- and grid-location of the disrupted components. Here, a failure is represented by a damaged power component such as a transformer, or an activated protected device from an open substation breaker to a blown fuse. The grid locations of failures are highly coupled with the device types and thus not used in this work. Geolocations are used mostly for visualization.

The first data set consists of 51,844 failures collected by a distribution system operator in New York from 2011 through January 2019. A total of 10,493,139 customers were affected, with customer downtime duration of 444,479 hours. This data set includes 60 major events (6 extreme and 54 severe). An additional 103 moderate failure events were identified that were not induced by the declared major storms but impacted the grid more than sporadic failures in normal daily operations.

The second data set consists of six major failure events in Massachusetts over the same time span causing 21,900 failures, affecting more than 1.6 million customers for a total of 808,221 hours power outage (see TABLE 1).

The failure events in New York and Massachusetts were induced largely by two types of weather disruptions: winter and non-winter storms. Using NOAA data repositories, the failure event times are matched with weather events of NOAA to categorize the failure events into winter and non-winter storm events (see TABLE 1). Winter events are defined as any weather disruption involving freezing temperature, rain, snow or cold wind. Non-winter events involve rain, hot weather, tornados, thunders or warm winds.

The failures were reported by customers. As such, some of the small failures might not be reported on time until discovered later. Some other outages, particularly those during recovery, may be induced by restoration itself that had to turn off the electricity supply for repair. Hence, the non-stationary property of failure-recovery processes are used to select a subset of the data samples for reliable analysis. The selection is based on the fact that most failures occurred at the beginning stage of a severe weather disruption are induced by exogenous weather conditions and have long durations. Thus, such naturally-induced failures are chosen for study. This is expounded upon under the hereinafter Temporal Characteristics For Two Stages Of Recovery.

There are limitations of the data. Data used by this work enable learning vulnerability and the behavior of recovery guided by commonly adopted policies. Additional data are informative on terrain conditions, topological characteristics of the grid and detailed impact on customers. Such data will help identify causal relations beyond behavioral learning, which is needed for enhancing services and policies as well as infrastructure enhancement. When such data are available, more sophisticated models can be used to characterize the impact of network structures on resilience. Further, additional micro data are needed from more US states. This will allow a scale up of the analysis and insights to more service regions as well as types of natural disasters.

The data from New York and Massachusetts is categorized into different types of failure events based on their severity as follows.

Failure Events Induced By Major Storms

Major storm labels in the data are used to identify major failure events. New York and Massachusetts declare a failure event as induced by a major storm based on two different given policies. Distribution system operators (DSO) use those policies to label individual failures from the major storms.

In particular, New York consists of 8 (sub-service) regions. A major storm is declared for each region individually. A region is classified as experiencing a major storm if either at least one customer loses electricity service for longer than 24 hours, or more than 10% of the customers in the region are affected. As such, the major storm criteria are only met sometimes in some of sub-service regions of a DSO. The failures in those regions are labeled as induced by major storms in our data sets. Such failures are thus extracted directly as the major failure events. More information about the regions can also be found in TABLE 2.

TABLE 2

| Region | Customers Served |
|---|---|
| Capital | 329,749 |
| Central | 285,932 |
| Frontier | 326,141 |
| Genesse | 99,535 |
| Mohawk | 138,313 |
| Northeast | 225,954 |
| Northern | 136,989 |
| Southwest | 105,031 |
| Total | 1,647,644 |

TABLE 2 provides information on the eight (sub-service) regions in New York. Customers served: number of customers served in each region by February of 2019 which is the end time of the data.

The major events are further into two categories based on the number of failures per event (event size): severe and extreme. If a major event caused more than 1200 failures, it is defined as an extreme event. Otherwise, the event is defined as severe as long as it causes more than 100 failures.

For Massachusetts a major storm is declared for the whole state if the governor declares state of emergency or at least 15% of the customers in the whole service region are affected. Six extreme major events all affecting more than 1200 failures are studied for Massachusetts. The moderate failure events obtained in the following sections are only for New York.

Moderate Failure Events

Moderate failure events are induced by weather disruptions that are not severe enough to be declared as major storms but differ from those of sporadic failures occurred in normal daily operations. Such moderate failure events happen frequently but have been studied insufficiently in the prior work. Thus, such moderate failure events need to be extracted from the unlabeled data samples, i.e., not marked from the major storms. To do so, it is necessary to first establish a baseline for the normal daily operation.

Failures occurring during the normal daily operation are considered as those when no weather event is present. Records (weather data) from National Oceanic and Atmospheric Administration (NOAA) is used to extract the time intervals when no weather event was recorded. This process is repeated for each year of the weather data. The resulting intervals are compared with the weather information in the failures data. If the weather information specifies any day which endures a weather event, that day is removed from the normal daily operation intervals. Such a comparison is to ensure the identified time periods indeed correspond to the normal daily operation, even though the weather information in the failures data is not completely accurate. Once the normal operation intervals are obtained, all the failures that occurred during those intervals are classified as the normal daily operation failures.

The baseline is then established by characterizing the behavior of the failures during the normal operation as follows. Nₚ represents delay in restoration as the number of pending failures that are yet to be repaired. The average and standard deviation of Nₚ, denoted as N̅ₙₚ and σₙₚ, are then defined over the whole service territory of the DSO. Further, the average and standard deviation of the number of pending repairs for the r-th (sub-service) region is denoted as N̅ₙₚᵣ and σₙₚᵣ, r=1, . . . , 8. These quantities, calculated from the data sets, characterize the behaviors of the failures occurred in normal daily operations. Such “normal behaviors” are used as a baseline for identifying moderate events.

Moderate failure events that deviated from the baseline of normal operations and were not labeled as major storms are now considered. The basic approach is to identify moderate failure events through detecting bursts of failures at certain time intervals and locations, that differ from sporadic failures during normal daily operations.

In particular, the start time of a moderate event is defined as the time instance when the number of pending repairs Nₚ exceeds significantly of that during the normal operation of each year, i.e., as Nₚ>N̅ₙₚ+σₙₚ. The end time is defined as the last instance when Nₚ is still above N̅ₙₚ+σₙₚ.

Once the start and end time epochs of the moderate events are identified, spatial information of a service region is added to refine the event identification. Given that major storm declaration is region-based, spatial processing for moderate events uses the eight sub-service regions as the spatial units. N̅ₙₚᵣ+σₙₚᵣ is obtained using the failure data in normal daily operations from a sub-service region r in a time window of 24 hours during the interval of the moderate event. If this region endures more failures than N̅ₙₚᵣ+σₙₚᵣ of the normal daily operation in any rolling window of 24 hours, those failures are considered as parts of a moderate event; otherwise, the failure data samples are removed from the event.

In certain instances, one moderate failure event starts while the impact of another is still ongoing. Such two events are then merged together. As an implementation detail, a threshold is used to specify the impact of a previous event. That is, if at least 10 customers are still experiencing outages from a previous event, the ongoing impact is significant enough for the merge to happen. The choice of the threshold is based on the experience of the service providers. The (merged) windows of failures form the resulting moderate events. Algorithm 1 summarizes how to identify moderate events below.

### Algorithm 1 Identifying Moderate Failure Events Using Unlabeled Failures Data:

1. Temporal processing: Define time intervals for normal daily operations using the records of NOAA and the failure data.
2. For each year j, compute the average and standard deviation of the number of pending repairs Nₚ for a normalized window of 24 hours, denoted as N̅ₙₚ^{(j)}+σₙₚ^{(j)}, respectively.
3. Let Nₚ^{(j)}(t) be the instantaneous number of pending repairs at time t. For year j, compute Nₚ^{(j)}(t) for every minute of the data. Now, to find the start and end times of the moderate events, pick tᵢ^{start} as the i-th instance where:

Nₚ^{(j)}(t)≥N̅ₙₚ^{(j)}+σₙₚ^{(j)} (1)

while

Nₚ^{(j)}(t−1)<N̅ₙₚ^{(j)}+σₙₚ^{(j)} (2)

Similarly, tᵢ^{end} is defined as the i-th instance where:

Nₚ^{(j)}(t)≥N̅ₙₚ^{(j)}+σₙₚ^{(j)} (3)

And meanwhile,

Nₚ^{(j)}(t)(t+1)<N̅ₙₚ^{(j)}+σₙₚ^{(j)} (4)
4. If event i starts when at least 10 customers are still experiencing power loss from event i−1, merge the two events with the start time (tᵢ^{start}) of event i−1 and end time (tᵢ^{end}) of event i. This step finalizes the temporal processing for start and end times of the moderate failure events.
5. Spatial processing: For each region r, r=1, . . . , 8 compute the average N̅ₙₚᵣ^{(j)} and the standard deviation σₙₚᵣ^{(j)} for a normalized window of 24 hours. This step is the same as step 2 except that the average and standard deviations are computed for specific regions rather than the entire service territory.
6. For each moderate failure event i and each region r, if the number of failures from event i in region r is less than N̅ₙₚᵣ^{(j)}+σₙₚᵣ^{(j)} in any 24 hour window of the event, the failures in that region are considered not impactful enough and thus excluded from the moderate event.

To make sure the spatial and temporal processing of moderate events are not introducing any bias into the dataset, NOAA data is used to verify that all the moderate events used in the study correspond to a weather event. The criterion for this verification is that the span of failure times in the data have at least 24 hours of overlap with a known weather event.

All the failure events above are further divided based on the type of weather event causing the failures. In particular, the same NOAA data is used to categorize failure events as winter storm or non-winter storms. Winter events are defined as any weather event involving freezing temperatures and rain, snow or cold winds. On the other hand, non-winter events involve rain, hot weather, tornados, thunders or warm winds. In New York, there were 3, 23 and 24 winter storms and 3, 31 and 79 non-winter storms for extreme, severe and moderate events, respectively. Among the six extreme events of Massachusetts, there is 3 winter and 3 non-winter failure events. The data summary of New York and Massachusetts is shown in TABLE 1.

Impact of Failures

In the previous section, different severities of weather events are defined, and the corresponding number of failures and customers affected are discussed. Deeper understanding about the impact of failures on the grid resulting from such weather events, however, requires more analysis. Thus, the distributions of failure characteristics namely number of customers affected and protective devices activated across moderate, severe and extreme events are studied. This analysis enables comparison of the failures' distributional impact when intensity of the weather events changes.

The first failure characteristic under study is failure size or number of customers affected by failures which is a measure of impact on customers. The distribution of such measure across different severity of events highlights how weather events sample the grid with respect to the impact on customers. As used herein, logarithmic intervals are used to study failure size as failure size can take values from one to thousands of customers and also, one customer group on its own is of interest for further analysis.

Therefore, five logarithmically divided categories are defined, denoted by Sis for i=1, 2, . . . , 5. These categories are defined as follows: S₁: c_{f}≥1000, S₂: 100≤c_{f}<1000, S₃: 10≤c_{f}<100, S₄: 1≤c_{f}<10, and S₅: c_{f}=1. As used herein, failures affecting more than 100 customers are categorized as large and those affecting less than 100 customers as small failures.

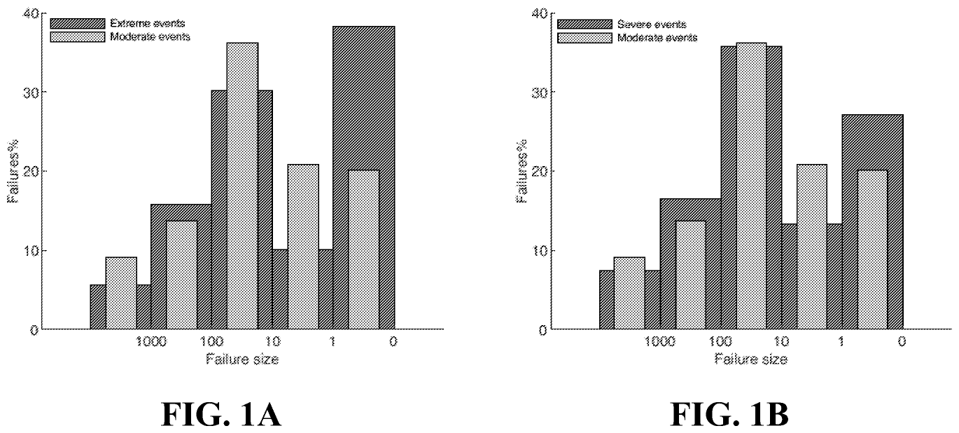

The failure size distributions of moderate events is compared against extreme and severe events in FIGS. 1A and 1B, respectively. It can be seen that one customer category contains significant percentage of failures and this percentage increases from an average of 20.1% for moderate events to 27.1% for severe and 38.3% for extreme events. In other words, the average percentage of one customer failures on the edge of the distribution grid increases significantly with higher severity of events. On the other hand, aggregation of failures to the level of large (c_{f}≥100) and small (c_{f}<100) shows very similar distribution among weather events. In particular, small and large failures take up (21.4% 78.6%), (24.1% 75.9% and (22.7% 77.3%) of failures for extreme, severe and moderate events, respectively. These results indicate that there is significant difference related to how edge of the distribution grid is affected going from moderate to extreme events. However, high level view of the grid shows strongly similar behavior in terms of number of customers affected across different severities.

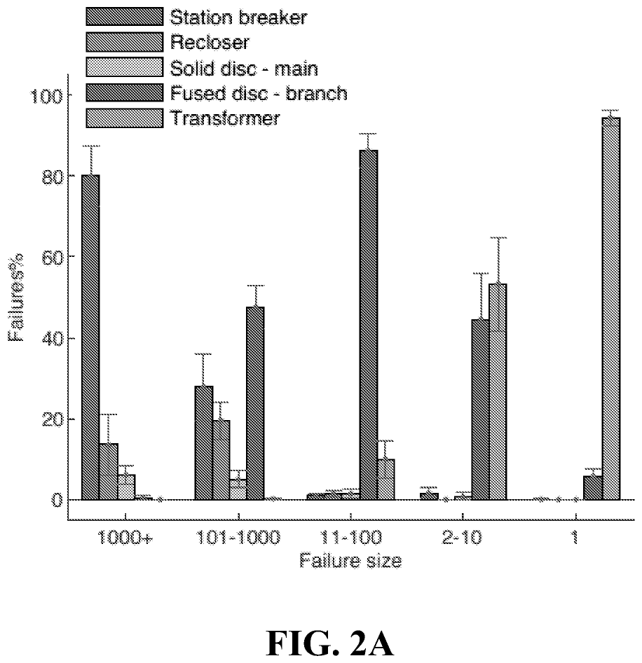

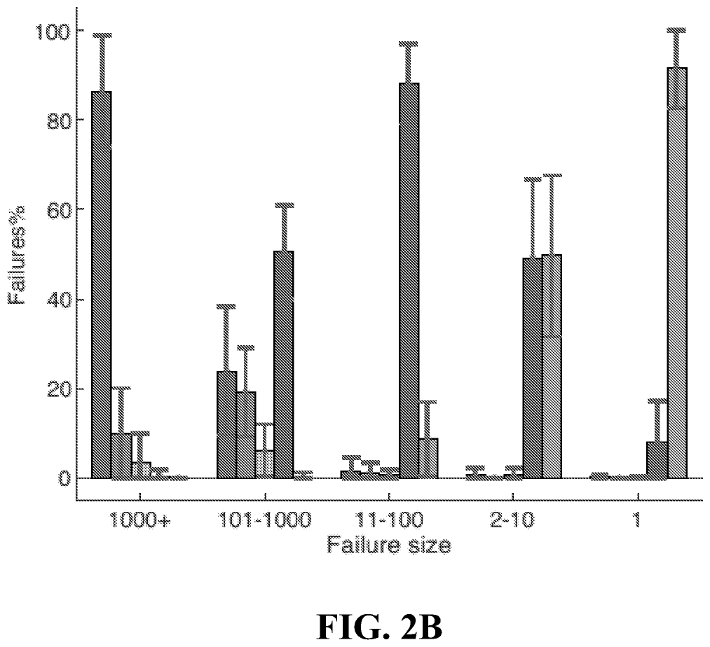

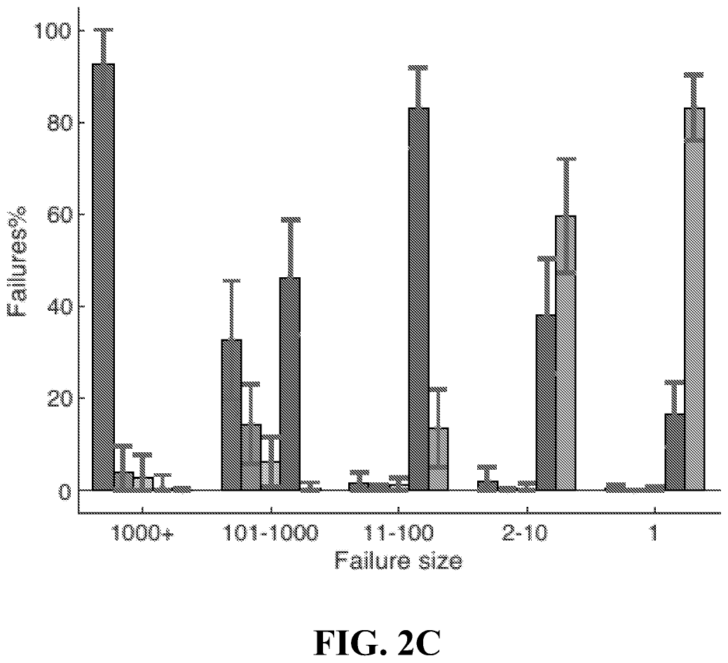

Failure size analysis highlights how distributional impact varies on customers based on the intensity of failure events. To further understand the failures' impact on the grid, activated protective devices can be studied as they characterize the physical structure of the distribution grid in the data. Therefore, the normalized distribution of disrupted devices for each category of failure size is shown in FIGS. 2A, 2B and 2C. On two extreme sides, 80%˜92.6% of the failures affecting more than 1000 customers are caused by station breakers and 83.1%˜94.4% of the one customer failures are as a result of activated transformers. In the middle, fused discs account for 83%˜88% of failures affecting between 10 to 100 customers.

A similar split between transformers and fused discs is seen for failure size between 2 and 10 which account for more than 95% of such failures. Finally, failure size between 100 and 1000 show a more balanced distribution of devices, with fused discs and station breakers having 45.6%˜50.4% and 23.9%˜32.2% portion of failures in this group, respectively. The overall distribution of protective devices for failure size categories show strong resemblance between moderate, severe and extreme events, although minor differences exist in values. This result further emphasizes the extent of similarity in distributional sampling of the distribution grid going from moderate to severe and extreme events.

Infrastructure Vulnerability

Q: “Is infrastructure vulnerability caused by major weather events, or does an inherent infrastructure vulnerability exist across weather events regardless of the intensity?” Infrastructure vulnerability is defined as whether a local failure affects small number of customers or can cause outage to large number of customers, thus making the distribution grid vulnerable. To answer these questions, failure scaling law is used which is a mapping between the total percentage of failures and total percentage of corresponding customers affected when failures are sorted from large to small. In particular, the mapping is between P_{c}(x) which is the probability of a customer getting affected by a failure causing outage to more than x customers and P_{f}(x) which is the probability distribution that a failure affects more than x customers. This formulation is extended so that failure scaling law is flexible enough to be conditioned on different variables like severity of weather events and additional failure characteristics. Additionally, the resulting failure scaling law is tested on all the 163 weather events in New York. The steps on how to obtain the empirical probability distributions are as below:

### Algorithm 2:

Given dataset D={xᵢ, dᵢ} for i=1, . . . , n, where xᵢ and dᵢ represent respectively the failure size and recovery speed of i-th failure in a failure event of size n. H_{w} corresponds to the set of variables related to weather event w causing failure i such as weather event type and severity. And, Gⱼ is defined as class j of failures with specific feature characteristics. The probability of failures affecting more than x customers P_{f}(x; H_{w}, Gⱼ) and the probability of a customer getting affected by a failure causing outage to more than x customers P_{c}(x; H_{w}, Gⱼ) for H_{w} and Gⱼ is estimated as follows:

$$\begin{matrix}{\tilde{P}}_{c} ( x ; {H}_{w} , {G}_{j} ) = \frac{{Σ}_{i ∈ {G}_{j}} {x}_{i} I [ {x}_{i} > x ]}{{Σ}_{i} {x}_{i}} & ( 5 ) \\ {\tilde{P}}_{f} ( x ; {H}_{w} , {G}_{j} ) = \frac{{Σ}_{i ∈ {G}_{j}} I [ {x}_{i} > x ]}{{N}_{f}} & ( 6 )\end{matrix}$$

Where N_{f} is the total number of failures in an event.

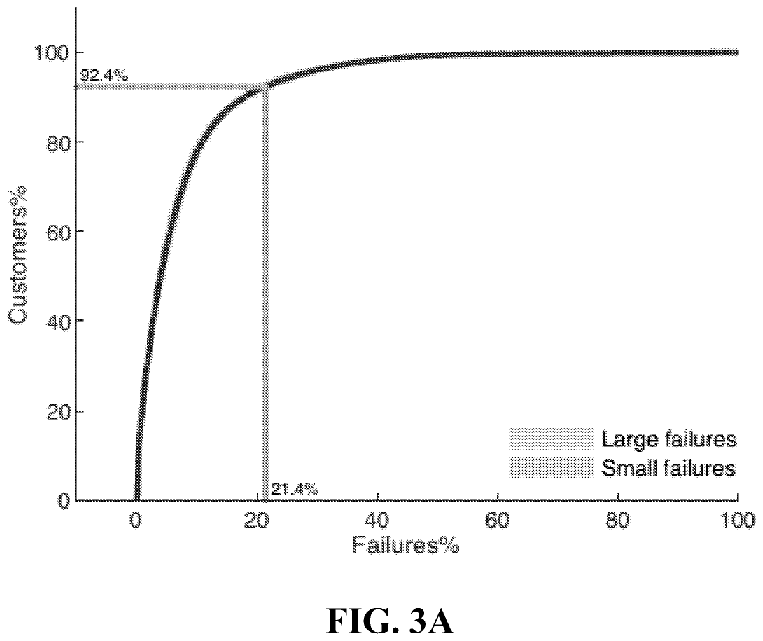

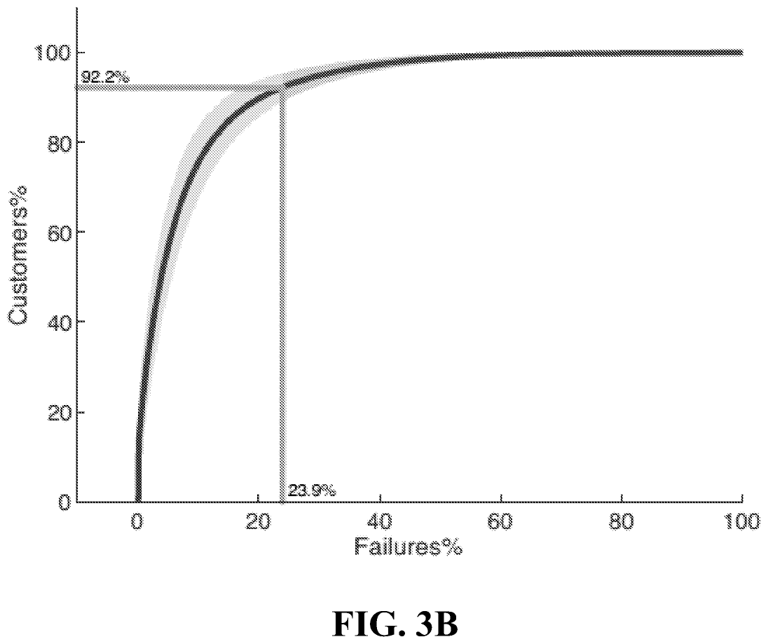

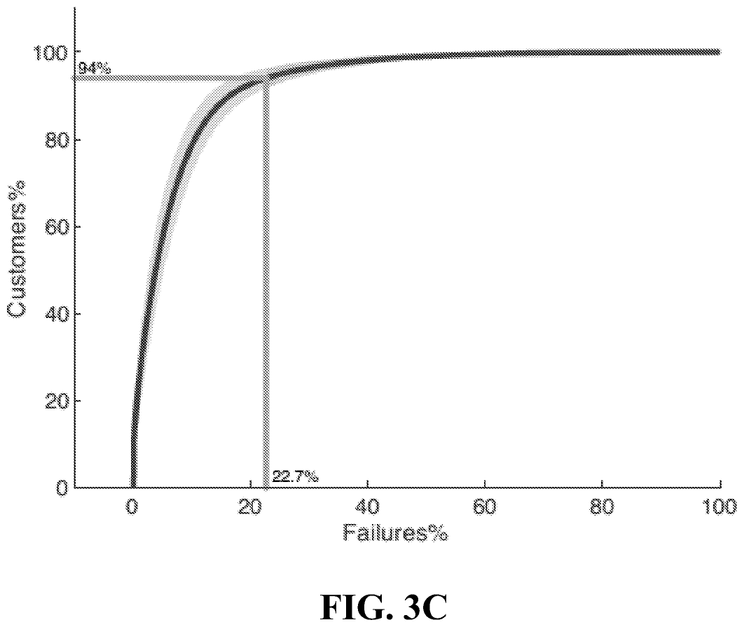

The failure scaling law for moderate, severe and extreme events is obtained in FIGS. 3A, 3B and 3C. Parts of the scaling law corresponding to large (affecting more than 100 customers) and small (affecting fewer than 100 customers) are plotted. It can be seen that large failures account for 21%˜24% of the failures and correspond to the high slope part of the scaling law affecting 92%˜94% of the total customers. This 20%-90% scaling behavior is consistent across weather events of moderate to extreme severity. This interesting result confirms that infrastructure vulnerability is inherent to the grid and is not caused only by severe weather events that make news headlines. The vulnerability is only exacerbated when the intensity if the events increase as it will be quantified hereinafter.

Service Resilience

Introduction

It has been estimated that weather-related outages cost around 20 to 55 billion dollars (USD) annually. Therefore, service resilience as the ability of service providers to minimize the impact of weather events from different severities on customers is of crucial importance to society, especially as the increasing impact of severe weather events results in more customers experiencing power outages at longer durations. The common policy used by service providers and emergency responders is to recover as many service users as fast as possible under resource constraints.

Lack of a deep understanding regarding the capabilities and limitations of such policy significantly hinders efficient solution planning for the shortcomings and mitigating the limitations. Thus, systematic field studies are needed to provide knowledge and rigorous benchmarks measuring how recovery services perform in face of failure events of different intensity. However, scarcity of granular data at a large scale in the form of focusing on single extreme events and spatial/temporal aggregation introduces additional challenges to such field studies.

A large-scale field study was conducted based on data science for operation distribution grid that evaluates recovery services from power failures. The study uses granular data on failure and recovery at two service regions in the US during 2011-2019. Here, the failures refer to both damaged power components and activated protective devices at the distribution grid. The first data set has 51,844 failures that affected over 10.4 million customers at a service area of 25,013 square miles in New York. The second data set consists of 21,900 failures that correspond to more than 1.6 million affected customers at a service region of more than 3,870 square miles in Massachusetts.

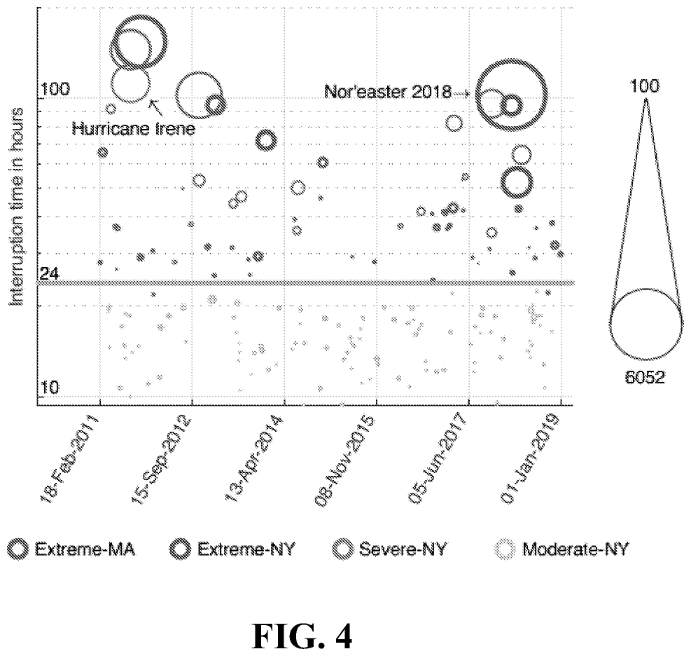

These failures are from 169 events of different severity as shown in FIG. 4: moderate, severe and extreme. In particular, 66 failure events were induced by the so-called major storms. The major storms are declared by New York and Massachusetts based on the respective policies. Twelve such failure events (six in each of the two states) are further considered as extreme based on the total number of induced failures and the longest downtime duration of 7 days.

Hurricane Irene in 2011 and Nor'easter in 2018 are two examples of the named major storms that caused widespread disruptions. The other 54 failure events from the major storms are not as extreme and thus referred to as severe failure events. An additional 103 moderate failure events were identified that were not induced by the declared major storms but impacted the grid more than sporadic failures in normal daily operations. Further, the diverse weather conditions that induce the failure events to winter and non-winter storms using NOAA data sets were categorized.

Overall, the service regions in New York and Massachusetts are under typical weather conditions in the northeast of the US. Both service regions collect the same type of data. Hence, the failure events from New York are used to study how recovery varies with respect to disruptions of different levels of severity. The data set from Massachusetts is used to reveal both the potential and challenges in generalizing this study to different service regions. The failure events in both states are used to study the resilience of recovery to different weather disruptions.

Problem Formulation-Unsupervised Learning of Recovery Behavior

A mathematical formulation is derived for obtaining new knowledge on recovery services from the data. The study evaluates the performance of recovery with the variables on failure characteristics and the restoration policy. The performance of recovery is not known. Neither is the relationship between the recovery performance and failure characteristics. Therefore, unsupervised learning is best suited for inferring new knowledge from the recovery behaviors and failure characteristics.

Let XϵRⁿ represent failure characteristics where n≥1. The failure size is one such characteristic, which is the number of customers affected by a failure. The type of disrupted devices is another failure characteristic, which includes substations as the primary energy sources at the distribution grid and transformers close to customer property. Both the failure size and type of disrupted devices characterize the infrastructure of the distribution grid.

XϵA represents a set (A) of values for the variables (e.g., 100 or more affected customers and damaged transformers at certain geographical coordinates). Let Y (0≤Y≤1) represent the recovery behavior on how fast a failure recovers, where Y is obtained by ranking the downtime duration from the shortest to the longest. Thus, YϵB represents the recovery speed, which is slow when B: 0≤Y≤y₁, or rapid when y₁<Y<1. The boundary between the slow and rapid recovery is chosen as y₁=0.5 for simplicity. Other feature variables exist (e.g., weather and terrain conditions) that vary from event to event and thus are considered as random factors.

The recovery speed (Y) and failure characteristics (X) are random variables that in general are statistically dependent. The statistical dependence of (X, Y) is represented by their joint probability distribution P (XϵA, YϵB). For example, the strong dependence between the recovery speed and failure size reflects the impact of the utility triage on restoration. The independence of the recovery speed and failure characteristics provides a baseline (P(XϵA)P(YϵB)). A metric (f_{A,B}) measures the degree of the dependence through a joint probability distribution relative to the baseline, where:

f_{A,B}=P(XϵA,YϵB)−P(XϵA)P(YϵB) (7)

The unsupervised learning is implemented by first estimating the empirical joint probability P(XϵA, YϵB) from data. Then the maximum coverage regions on (A, B) are obtained for f_{A,B} to exceed a chosen threshold of 5% of the maximum value. And, such a condition is satisfied with a sufficiently small error bar Err(f_{A,B}). The error bars are obtained through 5-fold cross validation for each event and averaged between the training and test data across a given type of failure events. Algorithm 3 shows the detailed steps of the implementation.

### Algorithm 3 how to Obtain the Inference Diagram by Computing Empirical F_{A,B}:

1. For each failure event of a given type (i.e., moderate, severe and extreme), divide the data into five train and test sets through 5-fold cross validation. Let k enumerate the folds, k=1, . . . , 5. Let \hat{f}_{A,B}^{tr,k} and \hat{f}_{A,B}^{te,k} be the corresponding f_{A,B}(X, Y) for training and test sets respectively.
2. For each k, obtain \hat{f}_{A,B}^{tr,k} and \hat{f}_{A,B}^{te,k} as follows:

\hat{f}_{A,B}^{tr,k}=E_{tr,k}(I(XϵA,YϵB))−E_{tr,k}(I(XϵA))×E_{tr,k}(I(YϵB)) (8)

\hat{f}_{A,B}^{te,k}=E_{te,k}(I(XϵA,YϵB))−E_{te,k}(I(XϵA))×E_{te,k}(I(YϵB) (9)

where E_{tr,k} and E_{te,k} are sample means over k-th training/test set and I is the indicator function.
3. Empirical f_{A,B} and the reported error for each event are defined as:

$$\begin{matrix}{\hat{f}}_{A , B} = \frac{1}{5} {\sum }_{k} {\hat{f}}_{A , B}^{tr , k} & ( 10 ) \\ Err ( {\hat{f}}_{A , b} ) = \frac{1}{5} {\sum }_{k} {\hat{f}}_{A , B}^{tr , k} - {\hat{f}}_{A , B}^{te , k} & ( 11 )\end{matrix}$$

Note that unsupervised learning from grid data has been developed in recent work. In particular, data from smart meters are learned through K-mean clustering algorithm to identify customer usage profiles. Unsupervised learning and clustering based methods; in particular Isolated Forests, have also been used to identify anomalies in the smart meter data on load consumption. Phaser Measurement Unit (PMU) data are learned through change point detection methods and Principal Component Analysis to detect and identify the types of different failure events. In those examples, unsupervised learning is used directly to learn patterns from the grid data. Herein, the unsupervised learning provides a mathematical framework for problem formulation over different variables. Related algorithms on clustering directly result from the formulation.

Four Categories on Recovery Speed and Failure Size

The unsupervised learning method results in two covariates emerging as pertinent among the multiple variables relating to our data, the recovery speed and the failure size. This is expounded upon under the hereinafter Unsupervised Learning For Recovery Behavior.

These two variables together reflect the impact of recovery policy (i.e., the utility triage) that prioritizes the sequence on restoration of failures with a high number of affected customers. Such prioritization is for non-critical customers, where critical customers such as hospitals and police stations have the highest priority to be restored power.

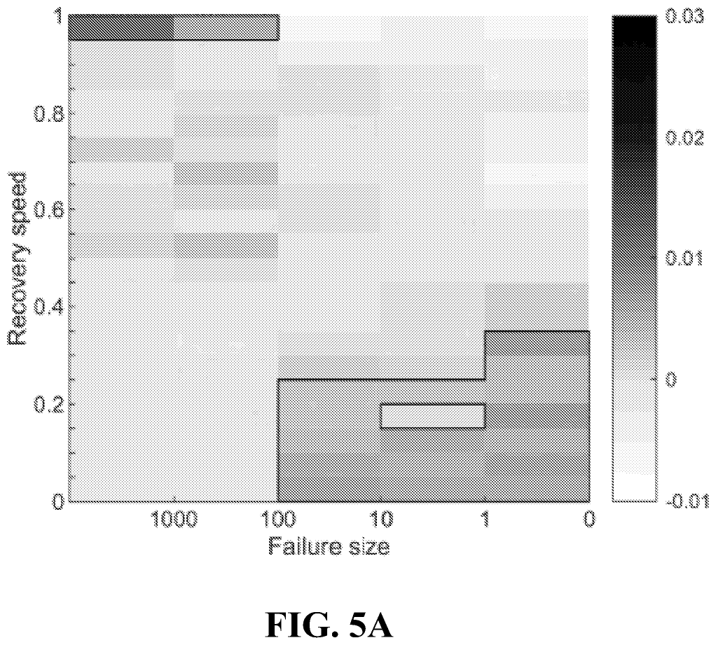

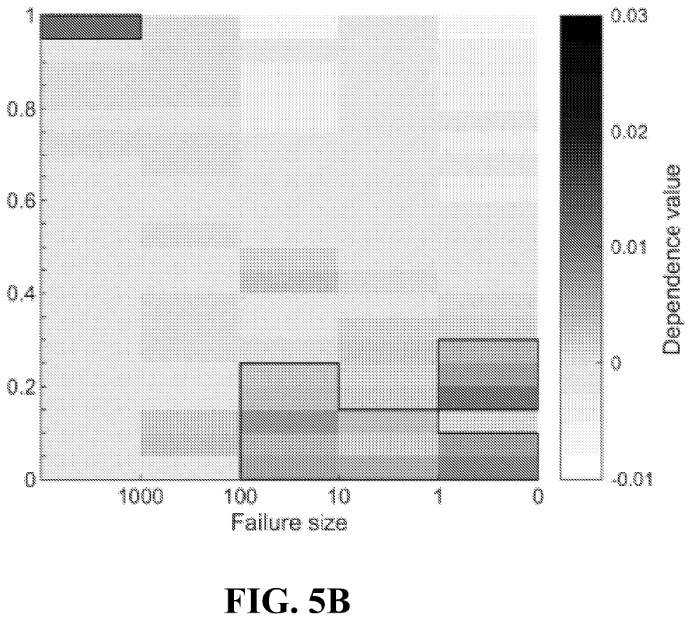

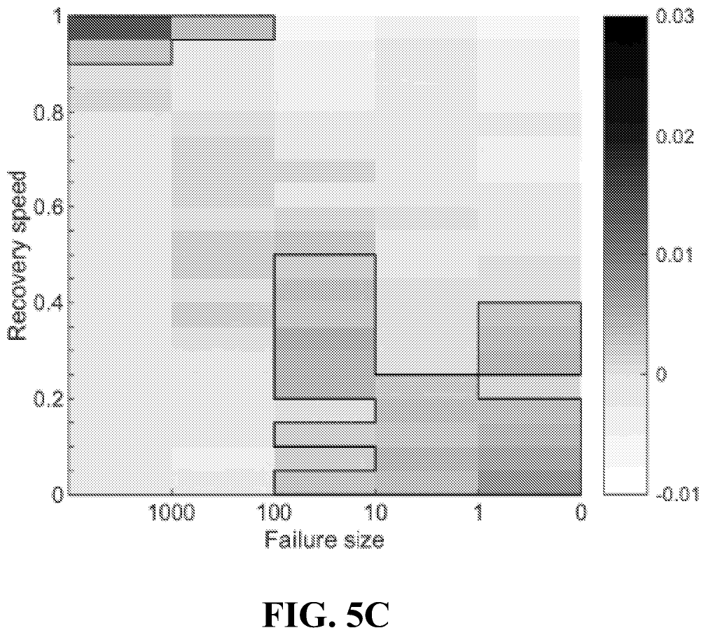

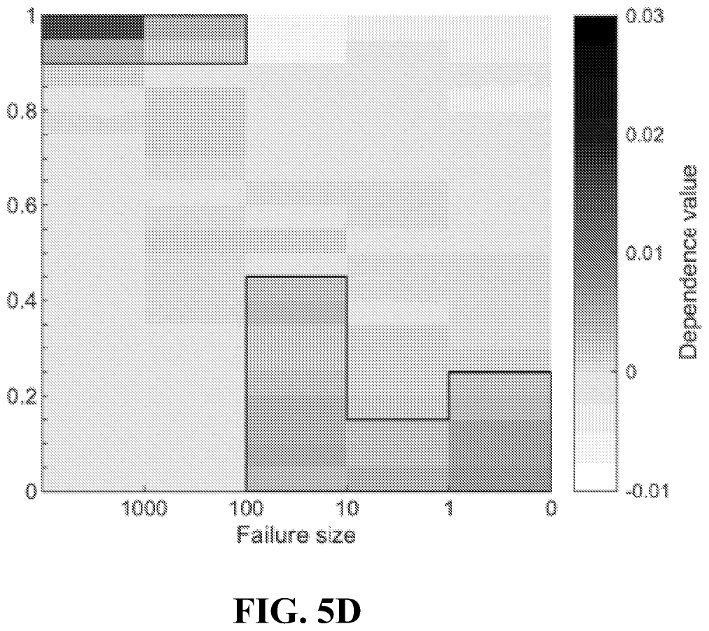

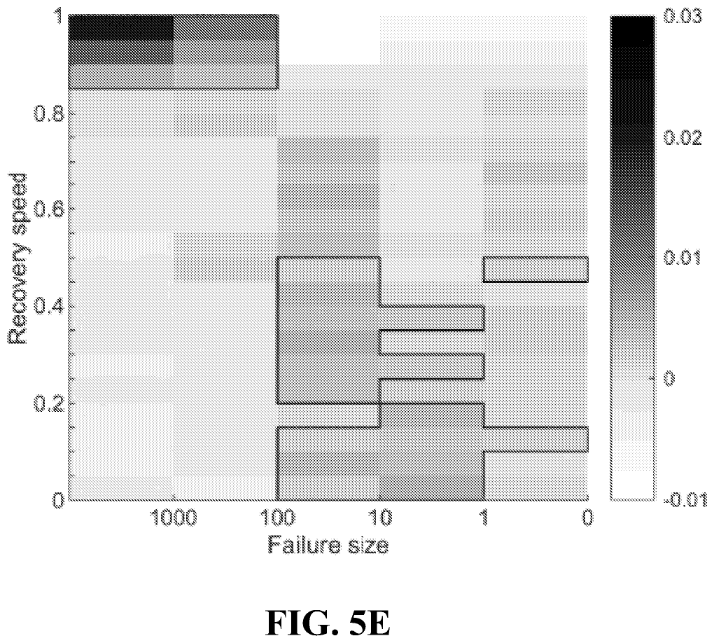

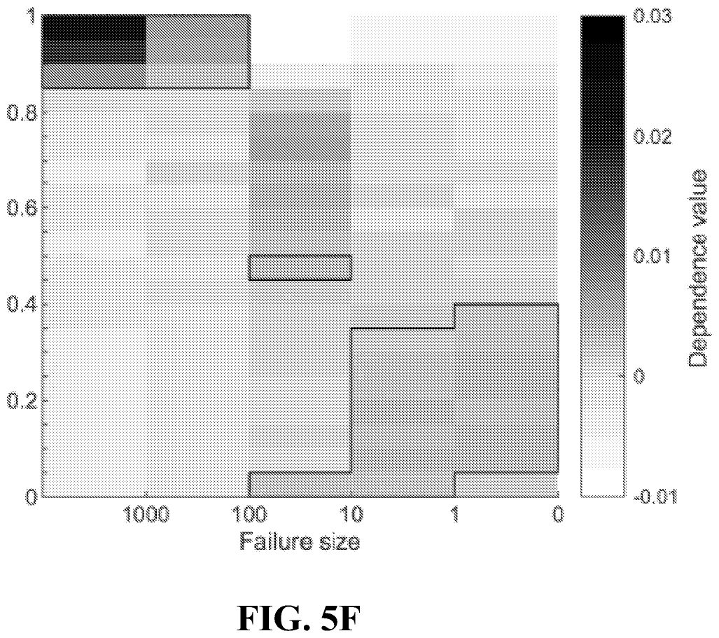

Such an unsupervised learning algorithm is applied to the pertinent covariates (failure size and recovery speed) for failure events of different severity from moderate to severe and extreme and two types of weather disruptions as winter and non-winter storms. The resulting clustered regions are shown in FIGS. 5A-5F, where the recovery speed and failure size are positively dependent. In particular, two clustered regions emerge showing strong dependence between recovery speed and failure size.

The first cluster corresponds to the so-called prioritized large failures, each of which affected more than 100 customers and has the shortest interruption durations. The cluster thus reflects that the large failures are potentially restored with priority soon after experiencing outages. The second cluster corresponds to the so-called prolonged small failures, each of which affected fewer than 100 customers. The long downtime durations are highly dependent of the small failure size, suggesting that the small failures often suffer delays in restoration. The rest corresponds to two other categories referred to as non-prioritized large and remaining small failures, respectively. The former consists of large failures affecting more than 100 customers but recovering slower than those in the prioritized-large cluster. The latter includes small failures that recovered faster than those in the prolonged-small cluster. Despite the differences in detailed shapes, these clustered patterns persist from the moderate to severe and extreme failure events as well as different types of weather disruptions.

The resulting four categories are defined in more details:
Prioritized large failures: Each large failure affected more than 100 customers, where the specific failure size (i.e., 100) results from the clusters. And, the recovery speed is ranked within the top 15% shortest downtime durations. Such a fast recovery speed is strongly dependent of the large failure size, showing that the large failures are often restored with priority and rapidly.
Non-prioritized large failures: These are the remaining large failures, each of which has the same large size of affecting more than 100 customers. The recovery speed, however, is below the top 15% and nearly independent of the failure size.
Prolonged small failures: Each failure affected fewer than 100 customers and the recovery speed is ranked within the bottom 50-100% of the longest failure durations. The slow recovery speed is strongly dependent of the small failure size, showing that those small failures experienced relatively long downtime durations.
Remaining small failures: Each failure has the same small size of affecting fewer than 100 customers and the recovery speed is ranked higher than the percentage defined by the bottom cluster. The recovery speed is nearly independent of the failure size.

Recovery Scaling Law

A key question on resilience is whether recovery services guided by the policies are able to meet the challenge of a wide range of disruptions from the moderate to severe and extreme. Therefore, failure size and recovery speed as the main covariates resulting from our unsupervised learning method are further studied to answer this question. The relationship between recovery speed and failure size signifies how recovery is impacted by the prioritization policy. Here, recovery speed is characterized by d as the top percent fastest recovery ranked by the failure durations from the shortest to longest. Failure size is denoted as x representing the number of affected customers.

To understand the relationship between the recovery speed and failure size, a recovery scaling law is defined as a mapping between two quantities. The first is the probability Pᵣ(d; [s, w]) that a failure is restored within the top d % fastest. The second is the probability P_{c}(x; [s, w]) that a customer is affected by a failure which causes outages for more than x users (i.e., x is the failure size).

In other words, Pᵣ(d; [s,w]) and P_{c}(x; [s,w]) are the empirical probabilities of the cumulative percentage of the interruption durations and cumulative percentage of affected customers, respectively. The scaling law is parameterized by the severity (s) of failure events and types of weather disruptions (w). The steps for obtaining the recovery scaling law are explained below.

### Algorithm 4:

Given dataset D={xᵢ, dᵢ} for i=1, . . . , n, where xᵢ and dᵢ represent respectively the failure size and recovery speed of i-th failure in a failure event of size n. H_{w} corresponds to the set of variables related to weather event w causing failure i. H_{w} consists of weather event type and severity [s, w]. And, Gⱼ is defined as class j of failures with specific feature characteristics. Here, Gⱼ corresponds to the four categories on recovery speed and failure size: prioritized large, non-prioritized large, prolonged and remaining small failures, thus j=1, . . . , 4. The probability of a customer being affected by a failure which causes outages for more than x users is estimated as P_{c}(x; H_{w}, Gⱼ) and the probability of a failure being restored within the top d % fastest Pᵣ(x; H_{w}, Gⱼ) as follows:

$$\begin{matrix}{\tilde{P}}_{c} ( x ; [ s , w ] , {G}_{j} ) = \frac{{Σ}_{i ∈ {G}_{j}} {x}_{i} I [ {x}_{i} > x ]}{{Σ}_{i} {x}_{i}} & ( 12 ) \\ {\tilde{P}}_{r} ( x ; [ s , w ] , {G}_{j} ) = \frac{{Σ}_{i ∈ {G}_{j}} {d}_{i} I [ {d}_{i} < d ]}{{Σ}_{i} {d}_{i}} & ( 13 )\end{matrix}$$

Such a recovery scaling law characterizes relationships between the percentage of customers recovered and cost as the portion of interruption durations. Importantly, the mapping characterizes how the recovery speed scales with respect to the different severity of failures and types of weather events. Both the recovery and failing scaling laws developed are motivated by prior work where the scaling properties in terms of empirical probability distributions can be quantified.

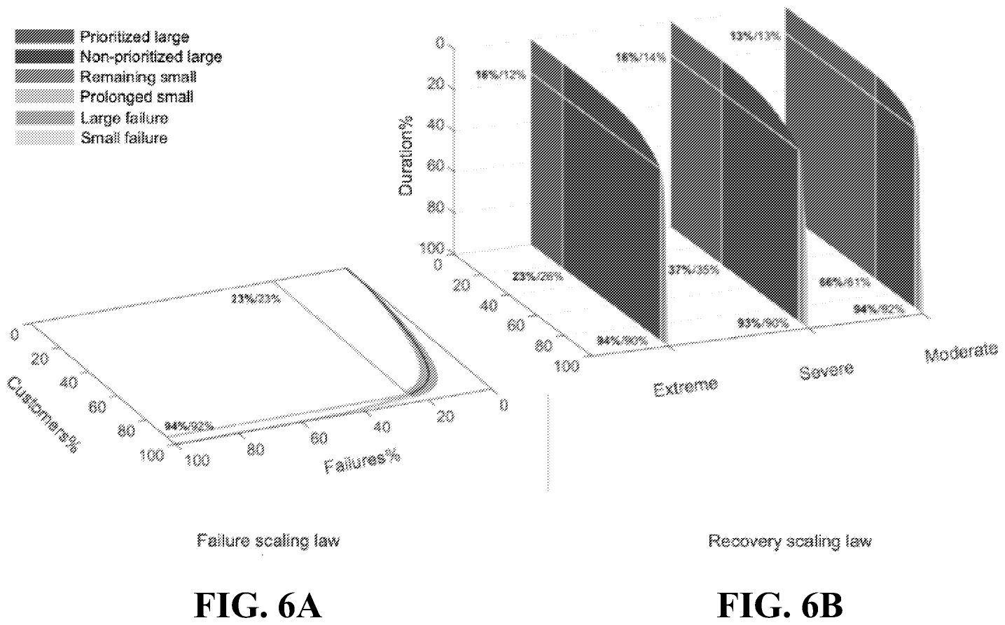

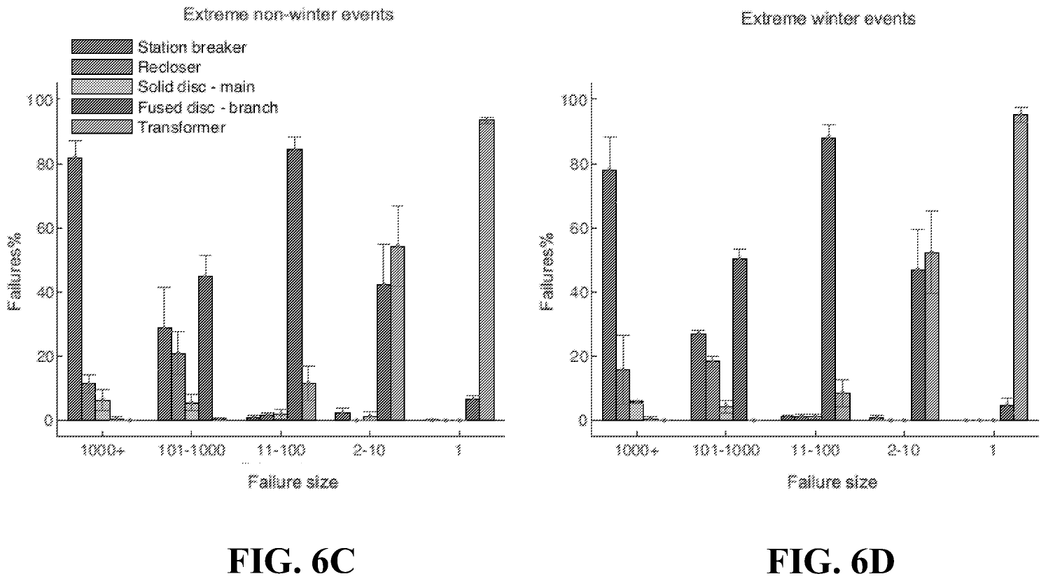

The empirical recovery scaling law in FIGS. 6A-6D is obtained using the data from the moderate, severe, extreme failures, winter and non-winter weather events in New York. Given each type of weather events and the severity, the recovery scaling shows a generalized (90-10) rule, where 90%˜94% affected customers consume 12%˜16% of the total interruption time. These ˜90% customers are affected by the large failures. Meanwhile, the small failures, while only amounting to less than 10% of the affected customers, consume 84%˜88% of the total interruption durations. Furthermore, the prolonged small failures affect less than 4% of total customers but take 60%˜70% of the total interruption time. Such disproportionality is present across the moderate, severe and extreme events shown by the recovery scaling curves of similar shapes. Additionally, the scaling laws differ by at most 5% between winter and non-winter storms. Hence, the scaling laws show that phenomenologically, the disparate recovery between the large and small failures is consistent to the typical restoration guided by the prioritization policy. The resulting restoration behaviors persist across different types of weather events and severity.

Interestingly, the recovery scaling was found to mirror the failure scaling obtained from the data. This failure scaling is an aggregation of all the three failure scalings obtained for moderate, severe and extreme events. This scaling in in FIGS. 6A-6D obeys a generalized (20-90) rule (20-80 in layman's terms). The failure scaling reflects an infrastructural vulnerability of the distribution grid, where a large failure affects a block of customers. The recovery scaling shows that restoration prioritizes a small number of such large failures (i.e., the top 20%) so that the majority (90%) of affected customers recover at the cost of a small portion (10%) of total interruption durations. In contrast, the prolonged small failures amount to a larger portion (˜37%) of all failures but affected less than 10% customers. Hence, the data analysis helps connect the two scaling laws, illustrating that the recovery services governed by the utility triage attempt to mitigate the infrastructure vulnerability.

Additional information on the types of disrupted devices enlightens how recovery is coupled with the structure of the distribution grid. For a given type of major weather disruptions such as non-winter storms, the prioritized large failures for the severe and extreme events consist of mainly (>89%) open substation breakers; and the non-prioritized large failures correspond to mainly (>40%) fused discs and more than 17% and 20% open station breakers and reclosers, respectively as shown in TABLE 3.

TABLE 3

| | Station | | Solid | Fused | |
|---|---|---|---|---|---|
| | Breaker | Recloser | Disc | Disc | Transformer |
| Prioritized-large | 89.8% (19%) | 4.1% (10%) | 1.6% (7%) | 4.5% (11%) | 0% (0%) |
| major | | | | | |
| Prioritized-large | 92% (10%) | 2.7% (5%) | 0.6% (2%) | 4.6% (8%) | 0.1% (0.8%) |
| moderate | | | | | |
| Non-prioritized- | 30% (14%) | 19.8% (10%) | 6.2% (5%) | 43.7% (11%) | 0.3% (0.1%) |
| large major | | | | | |
| Non-prioritized- | 23.8% (10%) | 17.2% (9%) | 8.3% (7%) | 50.2% (12%) | 0.5% (1%) |
| large moderate | | | | | |
| Prolonged-small | 0.2% (0.5%) | 0.7% (2%) | 0.6% (0.1%) | 54.9% (14%) | 43.6% (14%) |
| major | | | | | |
| Prolonged-small | 0.9% (1%) | 0.1% (0.4%) | 0.6% (1%) | 55.2% (11%) | 43.2% (11%) |
| moderate | | | | | |
| Remaining-small | 1.2% (3%) | 0.3% (0.7%) | 0.5% (0.7%) | 49% (13%) | 49% (13%) |
| major | | | | | |
| Remaining-small | 1.9% (2%) | 0.4% (0.7%) | 0.7% (1%) | 52.2% (9%) | 44.8% (9%) |
| moderate | | | | | |

TABLE 3 shows the average distribution of failed device types for the four inference regions (Prioritized large, non-prioritized large, prolonged small and remaining small). Standard deviations are shown in parentheses next to the average values.

It is well known that substations, as the main power sources of the existing distribution grid, have to be restored with priority to provide electricity downstream. Meanwhile, restoring the large failures requires identification and isolation of all failures downstream, for both repair and safety of customers. The time needed for failure identification increases with the scale of severe failure event. In contrast, the prolonged small failures correspond to damaged transformers and fused cutouts close to customer property as shown in TABLE 3. Furthermore, the distribution of the outaged devices is similar between winter and non-winter weather disruptions. Hence, the types of outaged devices correlate consistently with the failure size and thus the prioritization of recovery. This shows that the recovery sequence is constrained by the structure of the distribution grid, from substations at the top level of hierarchy down to customer properties.

Disparate Recovery Deepens in Severe and Extreme Events

The disparity in recovery deepens when the failure events become severe or extreme. First, the heightened disparity is due to the large failures that cannot be prioritized. The prioritized large failures consume less than 1% of the total downtime across the failure events of different severity. These prioritized large failures affected on average 1500 or more customers, each of which recovered in less than 0.1 hours on average. However, 29%˜38% more customers affected by large failures became non-prioritized, i.e., with longer downtime durations, from the moderate to severe and extreme disruptions as shown by the recovery scaling law. Further, the ˜30% increase of the non-prioritized large failures results in 47 times more average Customer Interruption Time (CMI) from the extreme disruptions than that of the moderate events.

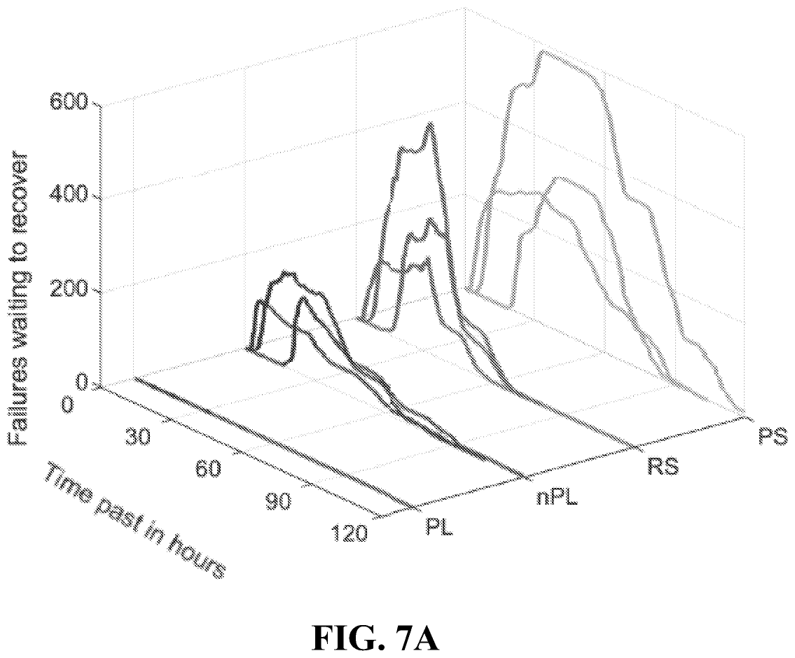

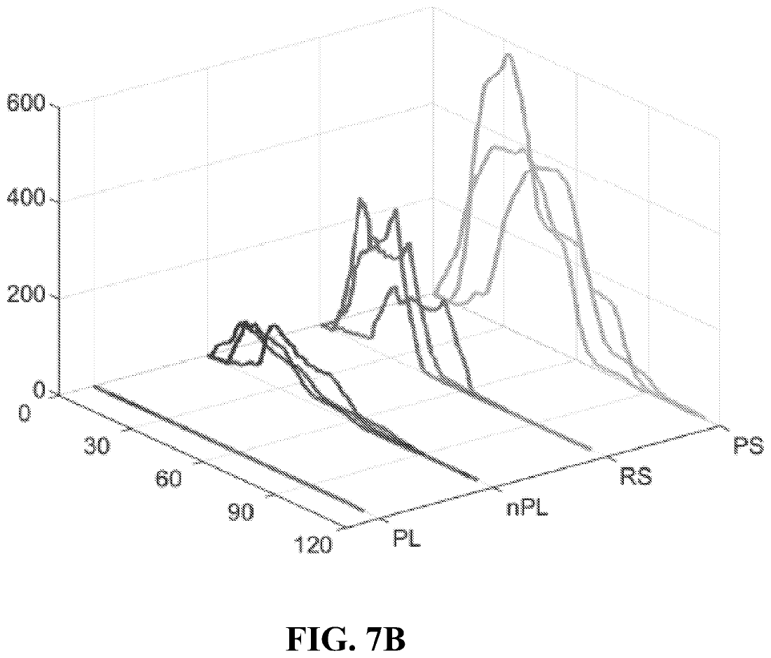

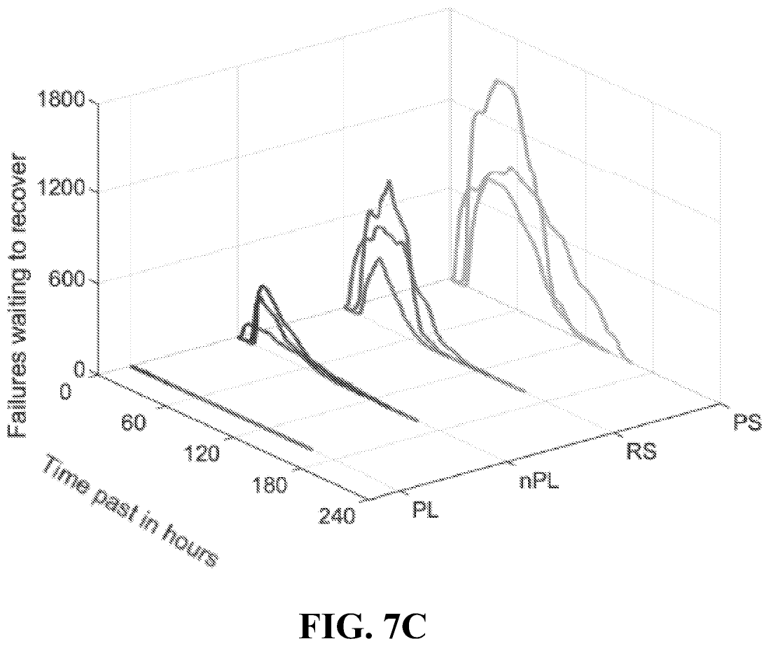

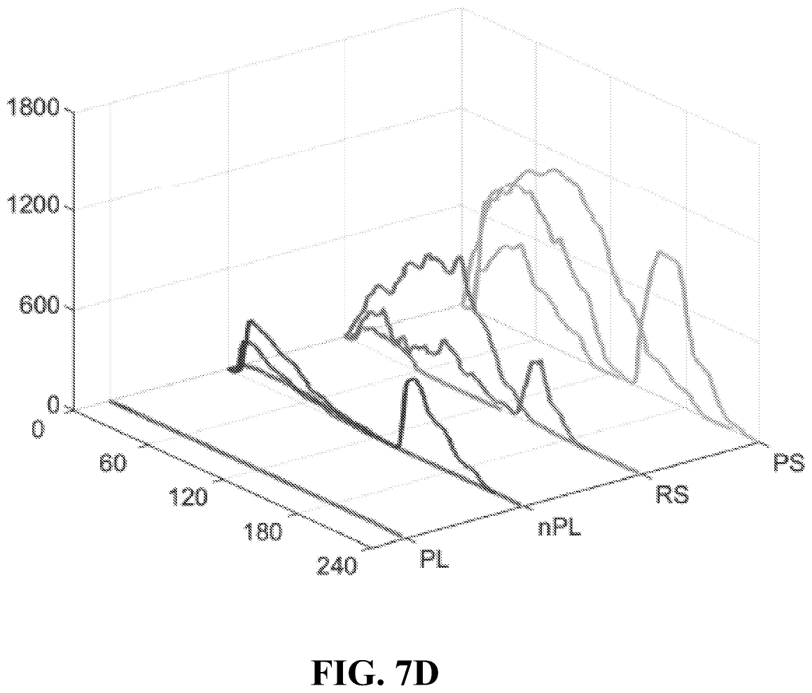

Dynamic evolution of recovery from extreme events shows vividly in FIGS. 7A-7D how the large and small failures recover differently throughout an entire disruption. At a given time during a disruption, the prioritized large failures have the fewest pending repairs at any given time across all the extreme events. There are significantly more prolonged small failures waiting for restoration than any other categories. Then, the peak value representing the worst impact is three times larger on average for the prolonged small failures than that of the non-prioritized large ones. Further, the non-prioritized large failures waiting for repair reach the maximum value about 24 hours earlier than the prolonged small failures. After the peak value, the non-prioritized large failures recover at a faster rate than the prolonged small failures. Therefore, small failures dominate delayed recovery during the extreme events. Such behavior persists across winter and non-winter weather disruptions.

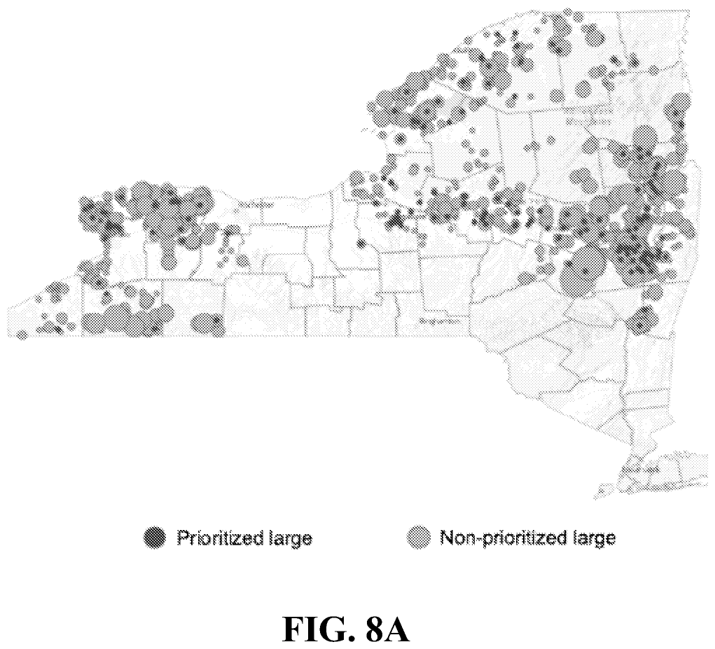

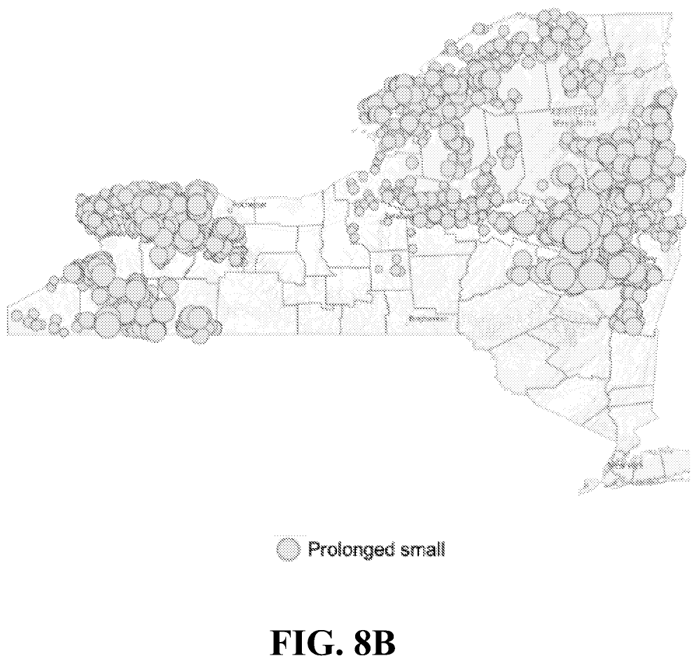

How significant is the deepened disparity? First of all, the extreme events induced a large number of non-prioritized large and prolonged small failures, illustrated by FIGS. 8A, 8B across the geographical service region at New York. The prolonged small failures stand out whose total downtime is 3.5˜5.7 times of that for the non-prioritized large failures. Furthermore, the prolonged small failures affected 60˜800 customers by a moderate disruption but 3500˜8700 users in an extreme event. The customers affected by the prolonged small failures regain power within 24 hours for the moderate events but experience interruptions as long as seven days for the severe and extreme disruptions. There is also a 20% increase in the number of smallest failures that affected one customer from the extreme disruptions compared with the moderate events (also observed by the Nor'easters in New Jersey 2018). On average, 48% (i.e., 1444) of those smallest failures in an extreme event are prolonged, representing the longest interruption time. Hence, more failures occur close to customer properties in the extreme events; and such failures are likely to experience long delayed recovery. This finding consolidates the importance of studying failures with long durations.

Generalization of Massachusetts

How does the present analysis generalize to different service regions? Consider an additional region serviced by the same distribution system operator but in Massachusetts. Like all regions, the recovery service in Massachusetts is guided by the same prioritization policy of minimizing the impact of failures on customers under constraints. A significant difference is that major failure events are declared by the governors in Massachusetts rather than the predefined declaration policies in New York. Hence, for fair comparison, this study focuses on the declared major failure events in Massachusetts that are extreme disruptions shown in FIG. 4 and TABLE 1.

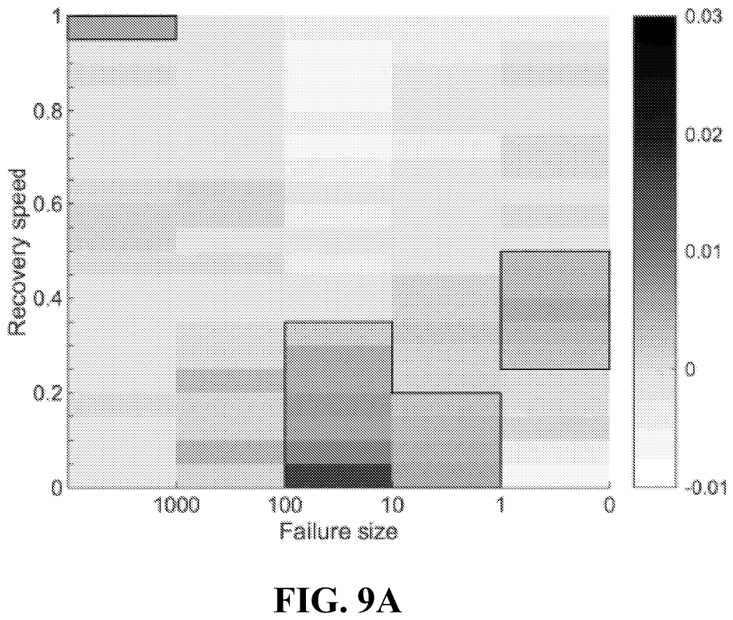

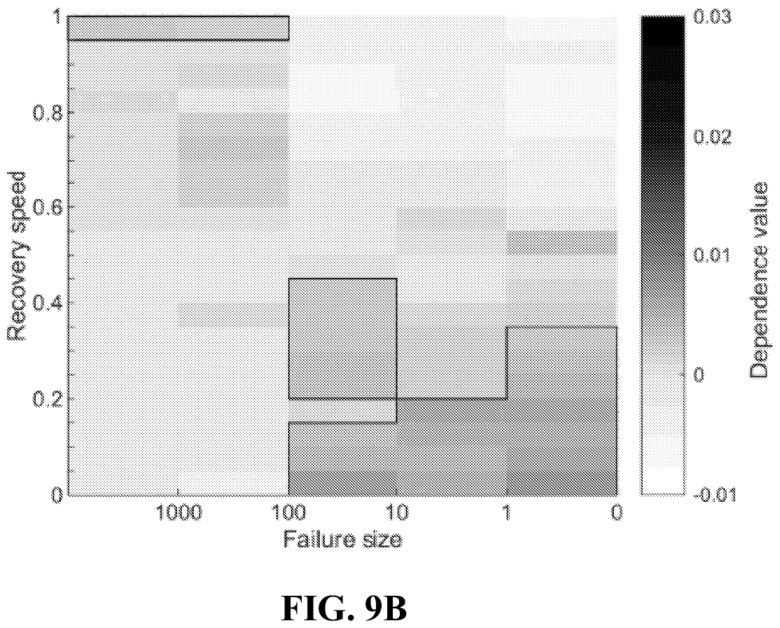

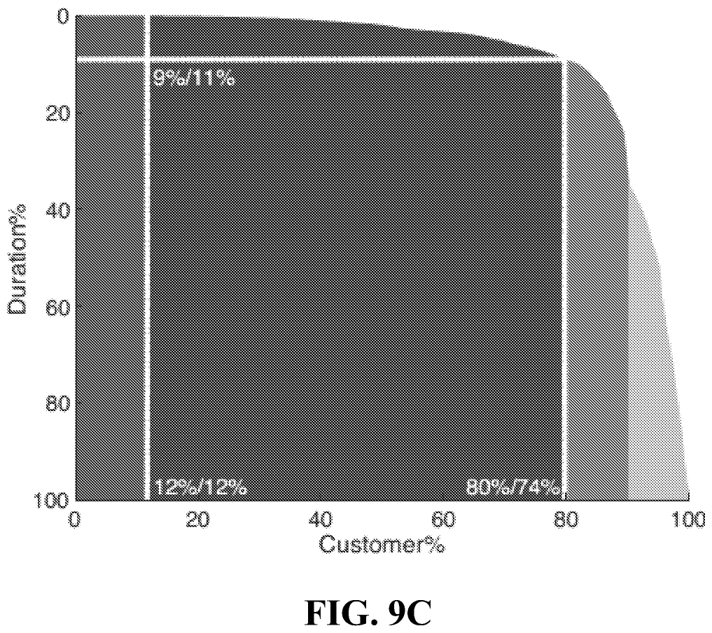

Analysis, using the data at Massachusetts, first observes similar behaviors of recovery to those of New York. The recovery speed and failure size show prominent clusters for the prioritized large and prolonged small failures, albeit the shapes of the clusters are somewhat different from those in New York (see FIGS. 9A, 9B). The resulting recovery scaling in FIG. 9C exhibits similar shape to that of New York, and is robust to winter and non-winter storms. Different from that of New York, the recovery scaling has 10%-14% reduction in the prioritized large failures, showing it is more difficult to prioritize recovery. Additionally, the prolonged small failures see 6% increase in the affected customers.

Significantly different from that in New York, the service region in Massachusetts has twice as many failures from the extreme events but is six times smaller geographically (see TABLE 1). As such, the peak number of failures waiting for repair doubles that from New York, for the non-prioritized large and prolonged small categories in FIGS. 7A-7D. Hence, the extreme failure disruptions appear to be more virulent and the recovery seems to be more challenging in Massachusetts.

Promise for Mitigating Fundamental Limitation of Recovery

Can we overcome the fundamental limitations of recovery? A futuristic scenario is explored where infrastructure enhancement is in place with distributed generation and storage. The premise is that recovery of customer services can be potentially conducted through future infrastructure enhancement rather than being constrained by the existing structure of the distribution grid. In fact, prior work has already demonstrated the possibility, for example, through abundant renewables in hurricane battered Puerto Rico and a framework of a distributed generation.

In this context, the question is “how and to what extent infrastructure enhancement can potentially help expedite recovery” rather than “how to perform enhancement or restoration”. In particular, to what extend such infrastructure enhancement is effective for circumventing the significant (i.e., ˜300%) increase of the non-prioritized large failures from moderate to extreme disruptions. The premise is that a large failure occurring at the distribution grid affects a big block of customers. And, the grid can reconfigure to connect the affected customers with distribution generation and storage when a failure occurs. This is motivated by recent work, where distribution grid operators have already begun to study distributed generation and storage for responding to power failures.

The recovery scaling law shows that among thousands of failures induced over an entire service region by an extreme event, only a small fraction are non-prioritized large failures as shown in FIG. 8A. Such a small fraction amounts to a large portion of affected customers shown by the coupled recovery and failure scaling laws in FIGS. 6A-6D. This implies that a fraction of the non-prioritized large failures, when restored rapidly, will benefit a large number of users and reduce total customer interruption time. Here, the idea is motivated by hardening the existing infrastructure guided by failure scaling. Instead, the present invention uses the recovery scaling laws to guide expedited restoration.

Failures were randomly from the non-prioritized large category using data from the extreme failure events occurred at New York. Distributed generation and storage was assumed to enable the chosen failures to recover rapidly as if being prioritized. In other words, x % of such failures are chosen at random for enhancement. The random selection is simulated for 100 different runs and the results are averaged. The enhanced failures were assumed to recover within 1 hour and thus, they will belong to the prioritized group post-enhancement. Then, the improvement in percentage of total customers affected and total CMI are computed for all six extreme events.

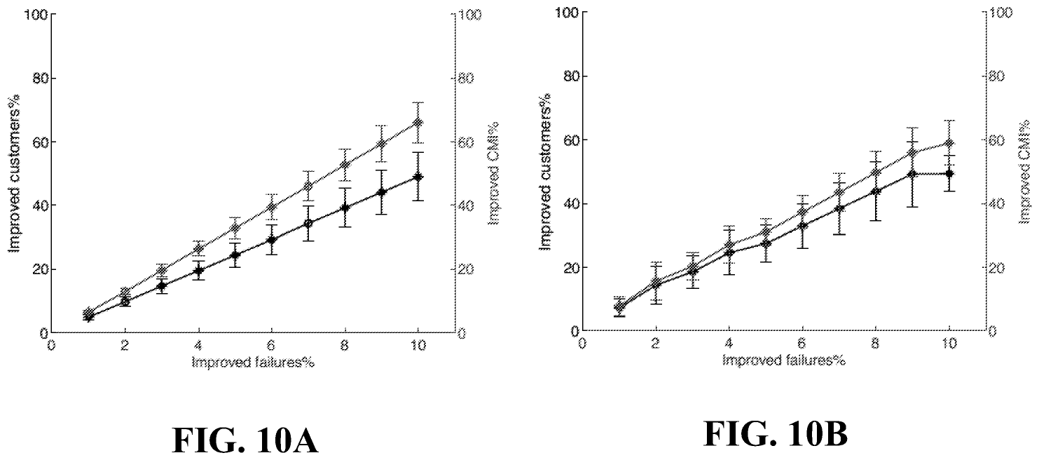

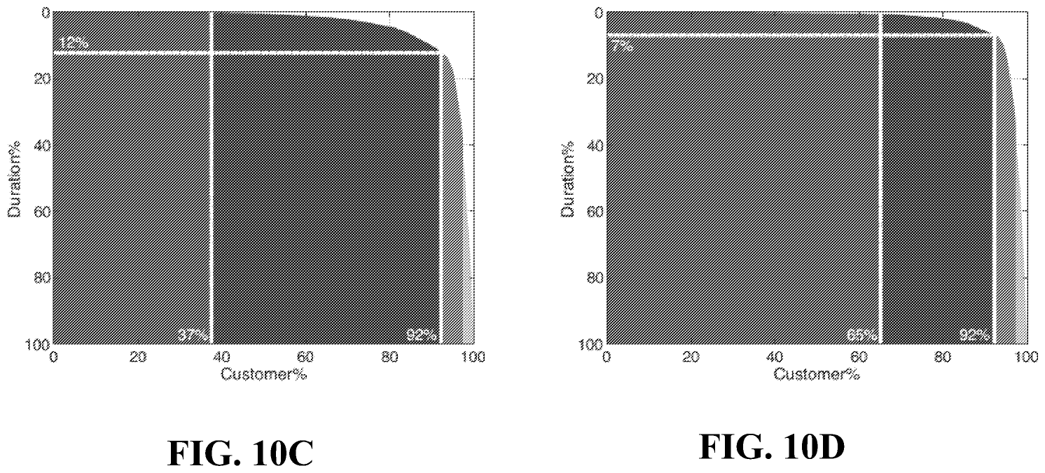

The analysis finds that the random enhancement of the non-prioritized large failures reduces, linearly, the percentage of total affected customers and customer interruption time (CMI) as shown in FIG. 10A. Importantly, the random enhancement reverses the degradation of recovery services for the extreme disruptions efficiently: ˜7% of random enhancement on the non-prioritized large failures results in ˜40% rapid restoration of the affected customers. That is, the random enhancement results in a recovery scaling for the extreme disruptions similar to that of the moderate events in New York in FIG. 10D. Similar improvements are obtained in FIG. 10B for the extreme failure events in Massachusetts. Such a gain results from the non-linear recovery scaling law. Further, it was noted that if structural information is available on distributed generation and storage, more sophisticated approaches can be devised for potentially better performance, including advanced recovery strategies and optimized grid reconfiguration.

Dynamic Resilience

Introduction

As described hereinabove, the impact of failures on service users and the distribution grid was compared across moderate, severe and extreme weather events. Additionally, an unsupervised learning framework and a new recovery scaling law were proposed to quantify effectiveness and limitations of service resilience and recovery performance of service providers in face of weather events of different intensity. Here, a dynamic spatiotemporal resilience metric is formulated to measure the cost impact on individual customers and across communities.

Standard evaluation criteria for energy infrastructure measure the robustness and reliability of power delivery during daily operations. Common metrics include the System Average Interruption Frequency Index (SAIFI), which is the average duration of interruptions per customer-year, the System Average Interruption Duration Index (SAIDI), which is the average number of interruptions per customer-year, and the Customer Average Interruption Duration Index (CAIDI), which is the average duration per interruption. However, the Institute of Electrical and Electronics Engineers (IEEE) recommends that these measures exclude failures caused by severe weather. A straightforward extension is to calculate separate performance measures for individual storm events, for example, the Storm Average Interruption Frequency Index (STAIFI) and Storm Average Interruption Duration Index (STAIDI). However, prior research indicates that STAIFI and STAIDI fail to characterize the dynamic impact of severe weather-induced power failures and such measures treat all service users uniformly.

Industry-wide criteria for evaluating the performance of electrical utilities during storms similarly treat all customers uniformly. For example, nomination criteria for the EEI's Emergency Recovery Award include the type of event, quantification of damage to the distribution system, and summary statistics on the number of customers with sustained outages, speed of restoration, costs associated with recovery, and key indicators of personnel safety. These criteria also reflect the priorities for many utilities when managing the failure response. For example, the press releases from Alabama Power and Georgia Power following Hurricane Michael in 2018 include information on the number of outages, miles of wire down, number of broken or damaged poles, number of fallen trees, number of transformers damaged, number of personnel mobilized, total hours devoted to restoration of power, and the speed until nearly all impacted customers had service restored.

Recent research proposes more advanced measures of resilience in order to capture spatiotemporal variation during a disruptive event, to couple failure, recovery and cost processes, and to permit comparisons across utilities and events. This work also highlights the need for developing measures of grid resilience to also capture variability in customer impact. By emphasizing the speed at which the grid is recovered and not the extent to which the utility mitigates the disruptive impact of the power failures on customers, existing metrics set aside the substantial heterogeneity in consumer vulnerability to severe weather induced failures. Research based on interviews with customers following significant outages, for example, finds that the costs of outages are concentrated among a few, high risk households.

Studies have found that the elderly and sick are at much greater risk during a power outage, particularly if they cannot find alternative ways to heat [cool] their homes in the winter [summer]. And estimates the costs of lost power for households in Germany based on an economic model and similarly finds the distribution has a long right tail. Substantial cost heterogeneity is also identified in studies of the costs of power outages to businesses. And conducted a meta-analysis of economic cost estimates for business firms and find, for example, that costs for a midday summer outage are largest for firms in the mining, manufacturing, and construction industries. And estimates that manufacturing, financial services, healthcare, and food retail bear the largest costs associated with power outages.

Other studies that specifically examine the impact of power outages on healthcare provision find hospitals are often underprepared for severe weather events that lead to outages that last for longer than backup generator capacity.

Thus, given the importance of capturing impact heterogeneity on customers, a dynamic spatiotemporal resilience metric is derived that incorporates the cost on customers at a specific time. The type of cost metric can be chosen based on the problem under study and it is assigned to each individual customer served by the distribution grid separately.

Coupled Failure, Recovery and Cost Processes

First, the notations used throughout the following are introduced in derivation of the resilience metric.

The following variables are defined:
t: Observation time variable
i: Index for failures.
j: Index for customers.
gⱼ: Geolocation of customer j in latitude and longitude.
zᵢ: Geolocation of failure i in latitude and longitude.
vᵢ: Start time of failure i.
v′ᵢ: Recovery time of failure i.
v′ᵢⱼ: Recovery time of customer j from failure i which can be different from v′ᵢ. It is assumed that a failure in general can have different location and recovery time from that of its affected customers.
dᵢ: Duration of failure i.
dᵢⱼ: Duration of customer j from failure i.
cⱼ(t): Cost variable of customer j which is a function of observation time t and customer profile.
Fᵢ(t): Failure i occurred at location zᵢ and time vᵢ, where Fᵢ(t)=1 for t≥vᵢ and Fᵢ(t)=0, otherwise.
Rᵢⱼ(t): Recovery of customer j at location gⱼ affected by failure i at (zᵢ, vᵢ). Rᵢⱼ(t)=1 represents recovery if t≥v′ᵢⱼ and Rᵢⱼ(t)=0, otherwise.
Gᵢ: A set of customer locations that are affected by failure i at (zᵢ, vᵢ).
Zᵢ: A set of failures locations that occur at time vᵢ.

Failure, Recovery and Cost Processes

Grid resilience is defined as a combination of three processes: failure, recovery, and cost. The failure process describes how nodes in the power grid that are in the normal state transition to a failure state. A node failure corresponds to either a damaged power component or an activated protective device. In either case, customers that rely on the failed nodes to receive electricity experience power outage. Importantly, the failure of a node can cause other nodes to lose power without being damaged. For example, a failed node upstream (such as an activated substation breaker) can cause nodes downstream to lose power (such as transformers or fused discs). All such nodes without power are in failure state by definition.

The recovery process captures the repair of failures, and as a result, restoration of power to the affected customers. Recovery is often characterized by failure duration, i.e., the period of time each node stays in the failure state. Given that a node being in the failure state does not necessarily imply that the node is damaged, recovery means restoration of power to that node whether it involves repair or not.

Finally, the cost process captures the joint impact of failures and recoveries on affected customers. It is straightforward to see why both failure and recovery processes are contained within the cost process, because the disruptive impact of storm on customers directly depends on how many failures occur as well as how fast those failures recover. An additional key factor in the cost process is the vulnerability of customers to failures. If more vulnerable customers experience more power outages than less vulnerable customers do, the cost of power failures is higher than if the reverse were true. Next, the cost process involving both failure and recovery processes is introduced.

Resilience Formulation

The dynamic nature of failure and recovery requires the cost process to be a function of time and geolocation. Thus, defining the instantaneous cost on customer j that is induced by failure i is defined as below:

Cᵢⱼ=cⱼ(t)[Fᵢ(t)−Rᵢⱼ(t)]I[gⱼϵGᵢ] (14)

where cⱼ(t) is the instantaneous cost imposed on customer j at location gⱼ and time t. cⱼ(t) is assumed to be independent of failures and recoveries. I[gⱼ ϵGᵢ] is an indicator function that equals to one only when gⱼ ϵGᵢ holds. gⱼ ϵGᵢ describes the relationship of how customers are connected to physical devices in the grid, where a failure i can induce outage to multiple customers. [Fᵢ(t)−Rᵢⱼ(t)] represents the duration of a lasting failure. Equation 414 assumes that an instantaneous cost on an individual customer takes a simple multiplicative form.

It should be noted that Cᵢⱼ(t) is only non-zero when the failure is on-going; i.e., Fᵢ(t)=1 and Rᵢⱼ(t)=0 which results in Fᵢ(t)−Rᵢⱼ(t)>0. In this formulation, it is assumed for simplicity, that only one failure occurs at a given time and geolocation. It is also assumed that each customer can be affected only by one failure at a time. This is consistent to the data used in all of the studies herein.

It is sometimes more intuitive to describe the cost process in terms of resilience curves, which relate time to the negative overall cost. We therefore calculate instantaneous resilience as Resᵢⱼ(t)=−Cᵢⱼ(t). For the remainder of the derivation, we use the term cost, however terms cost and resilience can be used interchangeably.

Spatial-Temporal Aggregation

The instantaneous cost process shows joint impact of failure and recovery on a single customer, at a particular time and geolocation. We therefore extend the formulation to enable studying the system at a larger spatial and temporal scale of choice, but with sufficient granularity of customers and the grid. Let R_{f} and R_{c} be discrete sets of failure- and customer-locations, respectively. Then, a spatially and temporally aggregated cost Q(R_{f}, R_{c}, t) is defined as below:

Empirical f_{A,B} and the reported error for each event are defined as:

$$Q ( {R}_{f} , {R}_{c} , t ) = {\int }_{0}^{t} {\sum }_{{z}_{i} ∈ {R}_{f}} {\sum }_{{g}_{j} ∈ {R}_{c}} {c}_{j} ( v ) [ {F}_{i} ( v ) - {R}_{ij} ( v ) ] I \{ {g}_{j} ∈ {G}_{i} \} dv \qquad ( 15 )$$

Note that the aggregations can be performed separately in time and space depending on the problem under study. Below, Q₁(R_{f}, R_{c}, t) and Q₂(R_{f}, R_{c}, t) represent aggregation for a single customer j over time interval [0, t] and over specific regions, R_{f} and R_{c} at time t, respectively.

$$\begin{matrix}{Q}_{1} ( {R}_{f} , {R}_{c} , t ) = {\int }_{0}^{t} {c}_{j} ( v ) [ {F}_{i} ( v ) - {R}_{ij} ( v ) ] I \{ {g}_{j} ∈ {G}_{i} \} dv & ( 16 ) \\ {Q}_{2} ( {R}_{f} , {R}_{c} , t ) = {\sum }_{{z}_{i} ∈ {R}_{f}} {\sum }_{{g}_{j} ∈ {R}_{c}} {c}_{j} ( t ) [ {F}_{i} ( t ) - {R}_{ij} ( t ) ] I \{ {g}_{j} ∈ {G}_{i} \} dv & ( 17 )\end{matrix}$$

where cⱼ(t)[Fᵢ(t)−Rᵢⱼ(t)] shows the instantaneous cost for customer j induced by failure i at time t>0.

The spatial summations Σ_{z}_{ᵢ}_{ϵR}_{_{f}}Σ_{g}_{ⱼ}_{ϵR}_{_{c}} account for customers in R_{c} that have a corresponding failure in R_{f} at an observation time t. Aggregating this cost over [0, t] sums the cost for all such customers from the start of the event till time t. The time interval of aggregation, R_{c} and R_{f} can be defined based on user needs. In the steady state when t→∞, all failures and recoveries occurred in R_{f} and R_{c} during a given failure event are included by the summations.

Special Cases

Using Equation 15 for aggregated spatial-temporal cost, a focus on special cases of cost variable cⱼ(t) enable studying different metrics of the distribution grid. In all the cases, it is assumed that customer j recovers when its corresponding failure i is restored; i.e., all the customers in R_{c} affected by a failure recover at the same time: dᵢⱼ=dᵢ and v′ᵢⱼ=v′ᵢ.

1. Time-Stationary Cost

The assumption here is that the cost imposed on customers varies at a longer time scale than the duration of a failure event. That is, the cost variable for customer j remains constant in time, cⱼ(t)=cⱼ, with cⱼ>0. Then, the resulting total cost up to time t is defined as:

$$Q ( {R}_{f} , {R}_{c} , t ) = {\sum }_{{z}_{i} ∈ {R}_{f}} {\sum }_{{g}_{j} ∈ {R}_{c}} {c}_{j} {D}_{ij} ( t ) I \{ {g}_{j} ∈ {G}_{i} \} \qquad ( 18 )$$

where Dᵢⱼ(t)=∫₀^{t}[Fᵢ(v)−Rᵢⱼ(v)]dv is the interruption duration for customer j induced by failure i,

$${D}_{ij} ( t ) = \{ \begin{matrix}0 , & if t \leq {v}_{i} \\ t - {v}_{i} , & if {v}_{i} < t \leq {v}_{ij}^{′} \\ {v}_{ij}^{′} - {v}_{i} = {d}_{ij} , & if t > {v}_{ij}^{′}\end{matrix} \qquad ( 19 )$$

Hence, the product cⱼDᵢⱼ(t) weights the cost on customer j by the current interruption duration at time t.

As each customer j recovers when its corresponding failure i is restored; i.e., dᵢⱼ=dᵢ, v′ᵢⱼ=v′ᵢ and Dᵢⱼ=Dᵢ. Then

$$Q ( {R}_{f} , {R}_{c} , t ) = {\sum }_{{z}_{i} ∈ {R}_{f}} {D}_{i} ( t ) {\sum }_{{g}_{j} ∈ {R}_{c}} {c}_{j} I \{ {g}_{j} ∈ {G}_{i} \} = {\sum }_{{z}_{i} ∈ {R}_{f}} {D}_{i} ( t ) {\sum }_{{g}_{j} ∈ {R}_{c} ⋂ {G}_{i}} {c}_{j} \qquad ( 20 )$$

Here, Σ_{g}_{ⱼ}_{ϵR}_{_{c}}cⱼI{gⱼϵGᵢ} is the aggregated cost of all customers in R_{c} affected by failure i, characterizing a community cost metric at time t. Note that the two terms, Σ_{g}_{ⱼ}_{ϵR}_{_{c}}I{gⱼϵGᵢ(zᵢ, vᵢ)} and Σ_{g}_{ⱼ}_{ϵR}_{_{c}}_{∩G}_{ᵢ} have the same meaning and will be used interchangeably.

In the steady state when t→∞, Q(R_{f}, R_{c}, ∞) is the steady state spatial distribution of aggregated costs weighted by interruption durations,

$$Q ( {R}_{f} , {R}_{c} , t ) = {\sum }_{{z}_{i} ∈ {R}_{f}} {d}_{i} {\sum }_{{g}_{j} ∈ {R}_{c}} {c}_{j} I \{ {g}_{j} ∈ {G}_{i} \} \qquad ( 21 )$$

where dᵢⱼ=v′ᵢⱼ−v′ᵢ as all failures recover by t→∞.

2. Constant Cost

If the cost variable is constant across event time and for a given community R_{c} meaning cⱼ(t)=C_{R}_{_{c}}, then Equation 20 changes to the following:

$$Q ( {R}_{f} , {R}_{c} , t ) = {\sum }_{{z}_{i} ∈ {R}_{f}} {D}_{i} ( t ) {\sum }_{{g}_{j} ∈ {R}_{c} ⋂ {G}_{i}} {c}_{j} = {c}_{{R}_{c}} I {\sum }_{{z}_{i} ∈ {R}_{f}} {D}_{i} ( t ) {N}_{{R}_{c}} ( i ) = {c}_{{R}_{c}} CMI ( {R}_{f} , {R}_{c} , t ) \qquad ( 22 )$$

where N_{R}_{_{c}}(i)=|R_{c}∩Gᵢ| is the total number of affected customers by failure i. In this case, Q(R_{f}, R_{c}, t) is equivalent to the constant cost c_{R}_{_{c}} multiplied by total Customer Minutes Interruption (CMI) in [0, t] for failure and customer neighborhoods of R_{f} and R_{c}. When cⱼ(t)=1, the aggregated cost process reduces to total CMI in [0, t].

3. Normalized Cost

In order to study other forms of the cost process that does not involve number of customers, a normalizing factor can be used for the cost variable cⱼ(gⱼ, t). In particular, if

$${c}_{j} ( {g}_{j} , t ) = \frac{1}{{N}_{{R}_{c}} ( i )} ,$$

then total failure durations of the event in [0, t] is measured by the cost process:

$$Q ( {R}_{f} , {R}_{c} , t ) = {\sum }_{{z}_{i} ∈ {R}_{f}} {D}_{i} ( t ) {\sum }_{{g}_{j} ∈ {R}_{c} ⋂ {G}_{i}} {c}_{j} = {\sum }_{{z}_{i} ∈ {R}_{f}} {D}_{i} ( t ) {N}_{{R}_{c}} ( i ) \frac{1}{{N}_{{R}_{c}} ( i )} = {\sum }_{{z}_{i} ∈ {R}_{f}} {D}_{i} ( t ) \qquad ( 23 )$$

Meaning the cost process changes from measuring CMI to total duration in [0, t]. Now, if the cost variable is defined as

$${c}_{j} ( t ) = \frac{δ ( t - {v}_{i} )}{{N}_{{R}_{c}} ( i )} ,$$

where

$$δ ( t - {v}_{i} ) = \{ \begin{matrix}1 , & t = {v}_{i} \\ 0 , & otherwise\end{matrix} \qquad ( 24 )$$

As the delta function is only non-zero at the exact time when a failure occurs, the cost process changes to total number of failures in the system.

$$Q ( {R}_{f} , R - c , t ) = {\int }_{0}^{t} {\sum }_{{z}_{i} ∈ {R}_{f}} {\sum }_{{g}_{j} ∈ {R}_{c}} \frac{δ ( t - {v}_{i} )}{{N}_{{R}_{c}} ( i )} [ {F}_{i} ( t ) - {R}_{ij} ( t ) ] I \{ {g}_{j} ∈ {G}_{i} \} dv = {\sum }_{{z}_{i} ∈ {R}_{f}} \frac{1}{{N}_{{R}_{c}} ( i )} {N}_{{R}_{c}} ( i ) = {\sum }_{{z}_{i} ∈ {R}_{f}} 1 \qquad ( 25 )$$

### Dynamic Social Resilience

Introduction

Standard metrics quantifying power grid resilience during severe weather events focus on the average performance of energy infrastructure to a greater extent than the distributional impact of power failures on customers and communities. However, recent research on the heterogeneous impact of power failures on customers suggests that evaluating the costs of storm-caused power failures requires measuring both the overall speed of recovery and the differential vulnerability of consumers and communities that can take many shapes or forms.

Here, a focus on the relationship between social vulnerability and the impact of power failures is investigated. The concept of social vulnerability captures multiple characteristics of individuals and communities that place them at greater risk to external stresses, like natural disasters. Some commonly included characteristics in measures of social vulnerability include socioeconomic status, age, minority status, language, quality of housing, and access to transportation. Taken together, these features of individuals and communities predict higher costs associated with natural disasters caused by of a lack of information about risks, shortages in the resources required to prepare for risks, and greater difficulty recovering once a disaster has occurred.

Recent case studies of hurricanes in the US demonstrate that more socially vulnerable communities tend to experience a more severe impact than less vulnerable communities do. For example, neighborhoods with a higher proportion of disadvantaged or vulnerable residents tend to experience more prolonged power outages. During Hurricane Irma, shorter power outages were also an important predictor of the speed at which households perceive themselves as having recovered from severe storms eight months later. The asymmetric impact of severe weather on power availability is consistent with other studies that demonstrate that vulnerable communities are affected more severely by natural disasters. During Hurricane Katrina, more socially vulnerable areas in New Orleans also experienced higher rates of drowning, slower rebuilding, and worse public health outcomes. A study found greater rates of outmigration following Hurricane Katrina and Hurricane Rita in more socially vulnerable communities than in less vulnerable ones. More recently, following Hurricane Harvey, more socially vulnerable communities reported higher rates of unmet needs and adverse event experiences.

Researchers continue to refine measures of social vulnerability to better reflect the intensity of social and economic disruptions following a disaster. Proposed indicators integrate attributes from existing research in the social sciences about what characteristics make individuals and communities more susceptible to disasters. The CDC's SVI is intended to help planners direct resources to communities that require more assistance during disasters and continued support once the disaster has ended. Specifically, SVI is measured on the county and census tract level and captures four domains of vulnerability: (1) socioeconomic status; (2) household composition; (3) minority status/language; (4) and housing/transportation. The appeal of SVI derives from its ease of use for policymakers and emergency responders. Further, although the predictive performance of various social vulnerability indicators varies across different disasters, a study shows that SVI correlates highly with other commonly-used alternative measures.

Here, the integrated approach from above is used that brings customer and community characteristics together with the existing tools for evaluating grid resilience. This approach serves as mathematical model that captures the dynamics of storm-caused power failures and recoveries and accounts for variability in the vulnerability of consumers and communities to power failures. Then, we extend it to the social setting and develop a randomization inference framework for examining the statistical relationship between the spatiotemporal distribution of failure and recovery and the variability in vulnerability across individuals and communities.

The method is applied to microdata on failure and recovery from Alabama, Georgia and Florida for Hurricane Michael, a Category 5 storm which hit the Southeast in October 2018. The Centers for Disease Control and Prevention (CDC) Social Vulnerability Index (SVI)—a metric that has been used extensively in prior studies examining the differential impact of disasters on communities—is used to measure the vulnerability of different communities in those states to power failures.

By bringing together data from the grid and data on customer vulnerability, the present method allows utilities and policymakers to ask novel questions about the distributional impact of power failures. Further, the present statistical methodology provides the flexibility to test hypotheses about potential causes of statistical dependence between economic and social vulnerability and storm impact.

Methodology

To analyze social vulnerability of customers affected by a severe weather event, the prior-described formulation is used to measure instantaneous resilience of customers. The cost variable in this formulation is CDC's SVI which varies at a longer time scale than that of a failure event; i.e., cⱼ(t)=cⱼ. Additionally, each customer recovers when its corresponding failure is restored. Therefore, total instantaneous resilience is defined as:

$$Res ( t ) = {\sum }_{j} {Res}_{j} ( t ) = - {\sum }_{{z}_{i} ∈ {R}_{f}} {\sum }_{{g}_{j} ∈ {R}_{c}} {c}_{j} ( t ) [ {F}_{i} ( t ) - {R}_{ij} ( t ) ] I \{ {g}_{j} ∈ {G}_{i} \} dv = - {\sum }_{{z}_{i} ∈ {R}_{f}} {\sum }_{{g}_{j} ∈ {R}_{c}} {c}_{j} {D}_{ij} ( t ) I \{ {g}_{j} ∈ {G}_{i} \} = {\sum }_{{z}_{i} ∈ {R}_{f}} {D}_{i} ( t ) {\sum }_{{g}_{j} ∈ {R}_{c} ⋂ {G}_{i}} {c}_{j} \qquad ( 26 )$$

$$where$$

$${D}_{ij} ( t ) = \{ \begin{matrix}0 , & if t \leq {v}_{i} \\ t - {v}_{i} , & if {v}_{i} < t \leq {v}_{ij}^{′} \\ {v}_{ij}^{′} - {v}_{i} = {d}_{i} , & if t > {v}_{ij}^{′}\end{matrix} \qquad ( 27 )$$

The current linear formulation of vulnerability and the interruption time associated with individual failures in instantaneous resilience of the grid permits us to use randomization inference to test for the statistical dependence between customer vulnerability and the power failures. In the randomization inference framework, a distribution of resilience curves is simulated under the assumption that customer vulnerability is (conditionally) independent from failure processes. Specifically, a null probability distribution for customer j is assumed, defined cⱼ⁽⁰⁾, and use it to generate a distribution of instantaneous resilience estimates under the null hypothesis of statistical independence Res₀(t).

$${Res}_{0} ( t ) = - {\sum }_{{z}_{i} ∈ {R}_{f}} {D}_{i} ( t ) {\sum }_{{g}_{j} ∈ {R}_{c} ⋂ {G}_{i}} {c}_{j}^{( 0 )} \qquad ( 28 )$$

By comparing Res(t) to the quantiles of Res₀(t) defined by a confidence level a, the hypothesis is tested that failure incidence at time t is independent of the vulnerability of the customers affected by those failures. Let Res₀^{α/2}(t) and Res₀^{α/2}(t) represent the upper and lower bounds, respectively, of the confidence interval defined by the null hypotheses of independence at time t.

Furthermore, by comparing the proportion of time that Res(t) falls outside the confidence region defined by (Res₀^{α/2}(t), Res₀^{1-α/2}(t)) over the time period spanning from t₀ to t₁, the hypothesis of independence over various phases of the failure event is tested. A focus is placed on the failure phase, when both the number of failures and pending repairs increase to their peak values along with the intensity of a weather event, and the recovery phase, when the storm is weakened and recovery takes place at a faster pace. Let t=0 be at the beginning of the observation window, t=t̅ when the number of device failures is at its highest value, and t=T be at the end of the observation window.

Define π(t₀, t₁, α) as the proportion of time between t₀ and t₁ that Res(t) falls outside the confidence region defined by α. Define π₀(t₀, t₁, α) as the distribution describing the proportion of time that a resilience curve generated under the null falls outside the confidence region during this time period. Let π*(t₀, t₁, α, β) represent the critical value of this distribution defined by β, that is, the value of π₀ such that 1−β percent of resilience curves generated under the null fall outside the confidence region (defined by α) a lower proportion of time over the period from t₀ to t₁. With this critical value in hand, one can test for statistical dependence over continuous periods of time. Specifically, if π(t₀, t₁, α)≥π*(t₀, t₁, α, β), then we reject the hypothesis that Res(t) is drawn from the null distribution Res₀(t) over the time period defined by t₀ and t₁ at confidence level 1−β.

Perhaps counterintuitively, π*(t₀, t₁, α, β) exceeds α considerably for extended observation windows. At any moment t, the probability that a resilience curve generated under the null hypothesis falls outside (Res₀^{α/2}(t), Res₀^{1-α/2}(t)) is equal to a. However, because a device that is in a failure state at time t is more likely to be in a failure state at t+1 than a device that is not in a failure state at t, resilience curves generated under the null that are outside the confidence region will tend to remain outside the confidence region (and those inside the confidence region will remain inside it). This intertemporal correlation leads the distribution π₀(t₀, t₁, α) to be fat tailed.

Interpreting Hypothesis Tests Given Customer Vulnerability

Importantly, outcomes of hypothesis tests are sensitive to the choice of the null distribution of customer vulnerability cⱼ⁽⁰⁾. There are many potential reasons that vulnerability and power failures could be statistically dependent. For example, elevated risk of natural disasters could lead to lower land values, which attract lower income households. Poorer communities may be slower to cut overgrown trees, which makes power lines more susceptible during severe storms. Or, homes located near hospitals or other critical infrastructure may also be located near other attractive amenities, increasing home prices. If the analyst wants to condition on these factors, then they need to be taken into account when choosing cⱼ⁽⁰⁾.

For example, if the analyst wants to test the theory that failures and vulnerability are unconditionally independent, then it makes sense to define cⱼ⁽⁰⁾ as the distribution of vulnerability across all customers in a given state. Rejection of the null hypothesis, then, implies that any of the potential mechanisms listed above could be the culprit. If, instead, the analyst wants to test a theory that vulnerability and power failures are independent conditional on the storm track, to control for the possibility that poorer communities tend to lie in the path of more hurricanes, cⱼ⁽⁰⁾ should take the correlation between the storm track and customer vulnerability into account. If the null hypothesis is rejected in this case, it will not be because higher vulnerability households experienced more severe weather. Instead, one of the other mechanisms is at play. In either case, the finding of statistical dependence does not imply a causal relationship. Instead, the results of the test identify statistically significant correlations and, depending on how cⱼ⁽⁰⁾ is derived, a set of potential mechanisms worth exploring in order to better understand why the correlation exists in the data.

Data and Model

This study uses data from operational distribution grids in Georgia, Alabama and Florida during October 2018 when Hurricane Michael hit all the three states. Overall, the data includes 147,744 recordings obtained by http://poweroutage.us/ from the websites of power utilities reporting outages in the above mentioned states. These reports are with rough time steps of 10 minutes apart from October 1st to October 30th of 2018. Each recording includes the following information that is relevant to this study: (1) Utility name, (2) State name, (3) County name, (4) City name(if available), (5) Time of recording, (6) Customers out at the time of recording, and (7) Customers served at the time of recording. Therefore, at the time of each recording, we know how many customers of a service provider in a county are served and how many from them experienced outage.

As described previously, we use the CDC's SVI to measure community-level vulnerability to power failures. SVI is defined as the quantile rank of social vulnerability on the county level which is restricted to fall between 0 and 1. Here, 0 represents the least vulnerable community and 1 represents the most vulnerable community in the US. The SVI ranking can be defined for counties within a state or the whole US. In this study, the quantile ranks are normalized across counties of the whole US. We assume equal vulnerability for all customers within a county. That is, if customer j and j′ are located in the same county, then cⱼ=c′ⱼ. SVI can also be defined over census tracts which are more granular spatial units compared to counties; however, county level SVI is used here to be compatible with our distribution grid data for Hurricane Michael.

Each recording in the data is connected to the corresponding SVI value based on county information. Thus, the resulting data give us a time series of customers out and served for each unique quadruplet (Utility, State, County, City) along with SVI value. For each time series, we assume that the number of customers reported out or served between two consequent time stamps does not change. To study the system at a state or county level, the time series from all utilities within the state/county are aggregated.

Descriptive Statistics

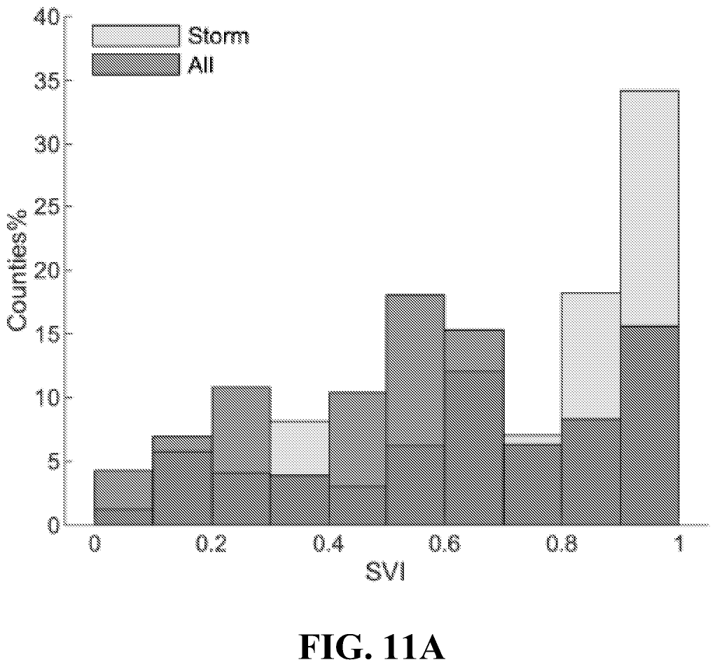

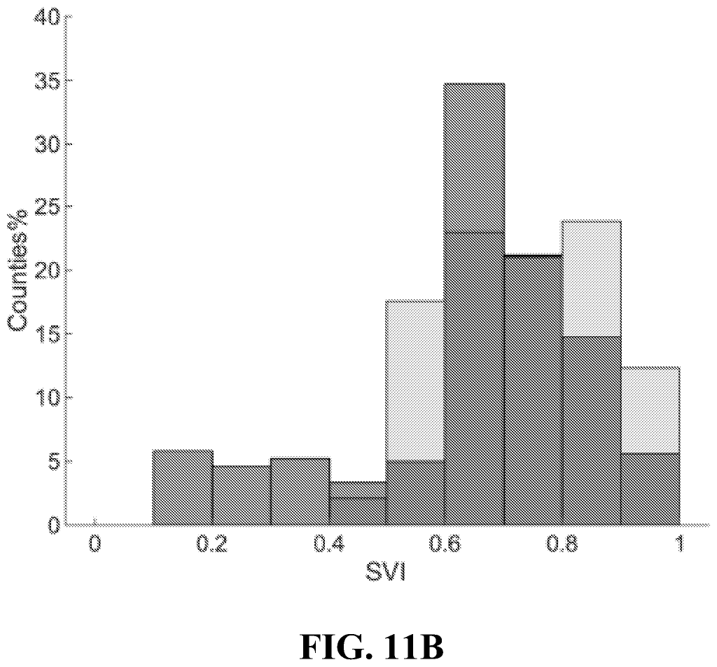

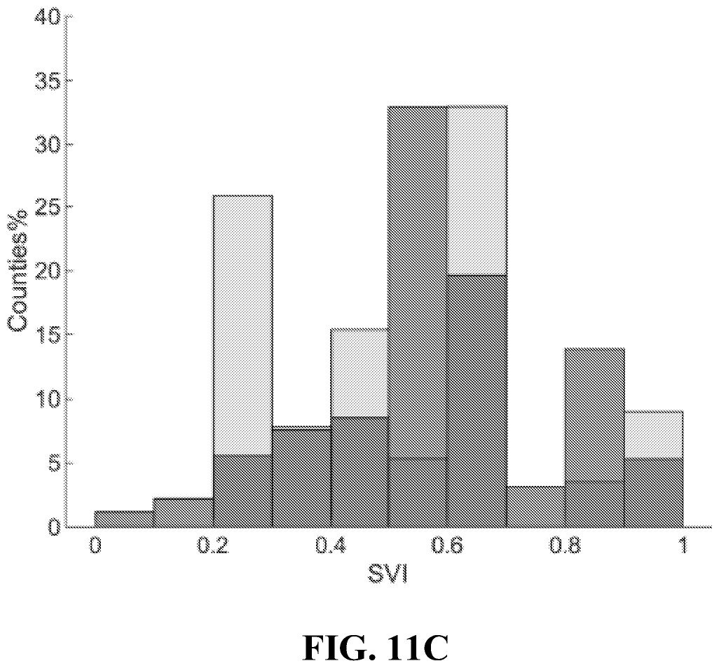

We begin our analysis by comparing the distributions of counties SVIs weighted by the maximum number of customers served in each county in month of October 2018. As described previously, the time series for each county is obtained by summing all the time series from the utilities in that county. The comparison, as shown in FIGS. 11A-11C, is for all counties in the data and the ones affected by Hurricane Michael over Georgia, Alabama and Florida. A county is considered affected by the storm if and only if at least 5% of the customers served in that county experience outage at some point in time assuming more than 100 customers are served at that time instance.

In Georgia, the customer-weighted SVI distribution of counties affected by the storm is clearly skewed towards more vulnerable communities as opposed to the baseline of all counties in the state (see FIG. 11A). In Alabama, this distribution shows slight shift towards more vulnerable counties when studying affected counties as opposed to all counties. However, the impact on more vulnerable customers is smaller than Georgia(see, FIG. 11B). In Florida, in contrast, higher percentage of customers in less vulnerable counties are affected by the storm. Hence, relatively more vulnerable communities were hit harder by failures in Georgia compared to the other two states.

Distributional Analysis for Georgia, Alabama and Florida

We use randomization inference to study the relationship between intensity of power outages and vulnerability of the affected customers. We first calculate vulnerability-weighted resilience curves Res(t), where cⱼ is equal to the SVI associated with the county where the customer experiencing outage is located. We then simulate vulnerability-weighted resilience curves under the null hypothesis Res₀(t) that the impact of power failures is uncorrelated with SVI using 2500 bootstrap samples. From this distribution, we derive confidence intervals (Res₀^{α/2}(t), Res₀^{1-α/2}(t)) and critical value π*(t₀, t₁, α, β).

The following steps were taken on Hurricane Michael data to obtain the null hypothesis for our randomization inference framework. First, we find the county SVI value corresponding to each recording in the data by matching FIPS (Federal Information Processing Standard) values in Georgia, Alabama and Florida with SVI data. Next, we remove recordings with unknown county names and counties where their last recording is earlier than October 29th with more than one customer out to filter missing data that can result in erroneous interpretation of the results. Throughout the experiments, the highest spatial granularity for SVI is county level. However, in the data we get one time series per unique quartet of (state, county, city, utility). So, the time series and any other relevant quantities are first obtained for unique quartets and then aggregated for each county or lower granularity levels.

To obtain the time series, a vector of time stamps from October 1st until the end of October 30th with 10 minutes steps is defined. Next, for each unique quartet of (state, county, city, utility), we map the recorded times in the data to the closest time in our time stamp vector. The assumption is that the number of customers experiencing outage between two subsequent time steps remains constant. Another assumption is that the number of customers out is zero if recordings are missing in the beginning or at the end of the time span. Once the time series for quartets are obtained, they can be aggregated into desired lower spatial granularity, for example: the whole region, county level or Georgia, Alabama and Florida.

Then, two scenarios are defined. In scenario one, we focus an all the counties in Georgia, Alabama and Florida. Here, for the null hypothesis, an SVI value is sampled from the SVI distribution of all the counties in Alabama, Georgia and Florida weighted by maximum number of customers served in each county (darker distributions in FIGS. 11A-11C). In other words, the SVI value for a given county is repeated N times in the distribution where N is the maximum number of customers served in that county. Note that, while the time series processing is based on quartets, the random SVI value remains the same across the quartets within the same county.

In scenario two, the focus is on the counties that experienced significant impact from the hurricane. To determine this significant impact, we use the 5% criterion. In this criterion, if at any recorded time, more than 5% of the instantaneous customers served in a county at that time are out, we mark the county as significantly impacted. The instantaneous number of customers tracked must be larger than 100. The resulting counties constitute the population of significantly impacted counties (lighter distributions in FIGS. 11A-11C). Then, the null SVI distribution is defined over this population of counties (defined by the 5% criterion) weighted by maximum number of customers tracked in that county. And one SVI value is sampled for each county.

In both scenarios, the SVI values are sampled with replacement from the null distribution and 90% confidence intervals are used for determining statistical significance of the results. To obtain the critical threshold π*(0, T, 0.10,0.10), 95% percentile of the percentage of the time a resilience curve generated under the null falls outside of confidence intervals of other null distribution resilience curves is used.

We conduct tests based on two different null distributions Res₀(t). The first draws cⱼ⁽⁰⁾ from the statewide distribution of SVI weighted by the number of customers served in each county. This analysis examines the unconditional relationship between outage intensity and social vulnerability of individual customers and does not adjust for the spatiotemporal evolution of the storm. In other words, the resulting null hypothesis is that all customers in a state have the same chance of getting affected by the storm regardless of vulnerability. The second null distribution draws cⱼ⁽⁰⁾ from a customer-weighted distribution only on the counties affected by the storm. This analysis, therefore, assumes stationary impact of the storm without directly accounting for the storm path. In other words, only customers in counties impacted by the storm have equal chance of getting sampled in the null hypothesis and affecting resilience. Thus, if there exists an aggregated larger impact on more vulnerable communities because of the storm, this scenario captures it.

Finally, we provide methodology on how to account for the storm path that requires data not available in this study. Such data include specific failures with corresponding start and end time, geolocation and number of customers affected. In this case, the null hypothesis resilience can be defined over the census tracts (higher granularity than counties) at any observation time if the geo information on the location of failures allows it. Then, the null distribution controls for the possibility that the relationship between outage intensity and social vulnerability is a result of the dynamic heterogeneous impact of the storm itself. Therefore, statistically significant deviation from the null here implies that more vulnerable communities are impacted more severely due to other factors than the severity and path of the event itself, such as recovery performance of the utility and robustness of the grid.

Scenario 1: No Spatiotemporal Variation

In the first scenario, we derive the null distribution c) from the empirical distribution of SVI in the whole state. This is a good approximation of the distribution of vulnerability-weighted resilience curves under the assumption that each customer in the state, regardless of their vulnerability, has an equal probability of experiencing a storm-caused power outage. Because the null distribution is independent of the storm track, this scenario does not differentiate between whether the storm itself impacted more vulnerable communities more intensely, the power grid is more robust in less vulnerable communities, or the utility's recovery response is correlated with community characteristics.

We first plot the observed vulnerability-weighted resilience curves for all states against the null distributions conditional on the time since the start of the storm. When the observed curve lies below the boundary defined by α=0.10, it indicates that more vulnerable communities were more affected by power outages at time t. When the observed curve lies above the boundary, it indicates that more vulnerable communities are less affected by power outages at t.

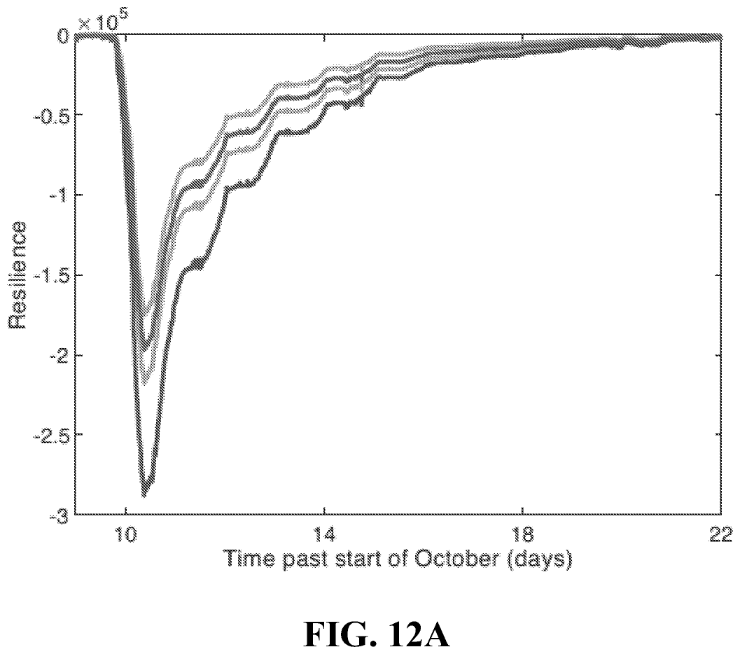

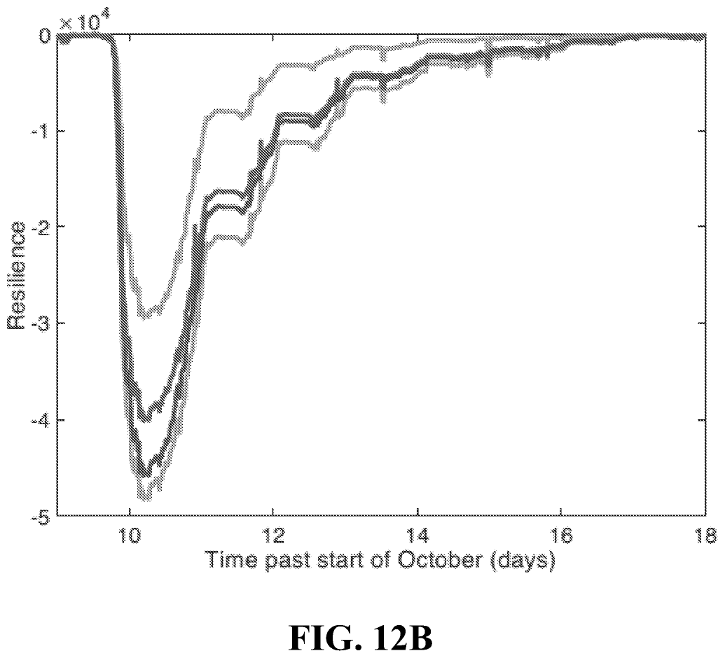

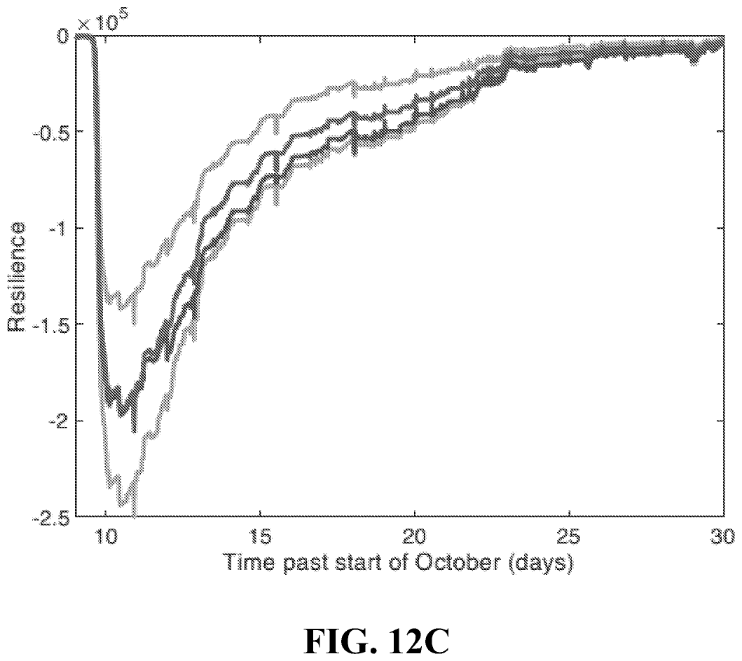

In Georgia, more vulnerable communities experienced more severe outages for almost the entire duration of the storm as demonstrated in FIG. 12A. FIG. 12B, which applies the same analysis to Alabama, tells a less consistent story. While more vulnerable communities were more severely affected especially around October 10th to 12th, the observed vulnerability-weighted resilience curve falls within the confidence intervals for the whole duration of the event, which suggests a lack of statistical significance in dependence between vulnerability and outage intensity. For Florida, as shown in FIG. 12C, the null and vulnerability-weighted resilience curves are very similar for majority of the early part of the event indicating similar impact on more vulnerable communities. However, as it gets past October 13th, the impact on more vulnerable communities increases and the vulnerability-weighted resilience curve falls outside of the confidence intervals towards October 25th, although by a small margin.

Next, we analyze the relationship between vulnerability and the severity of power outages for different phases of the storm. We analyze the statistical dependence between vulnerability and outage severity for three periods of time. The first spans the entire duration of the hurricane. The second—the failure phase—begins at the start of the hurricane and ends at the trough of the unweighted resilience curve, i.e., the moment when, under the null, the costs of the weather-caused outages is maximized in terms of number of customers waiting to recover. The third—the recovery phase—begins at the trough and ends at the end of the storm.

For the entire storm, the observed vulnerability-weighted resilience curve departs from the confidence interval for 96% of the time in Georgia, 37% in Florida and only 0% of the time in Alabama. The critical values value π*(0, T, 0.10, 0.10) for Georgia, Florida and Alabama are 55%, 59% and 87%, respectively. As a result, in Georgia, we reject the null hypothesis that vulnerability and the impact of power failures are independent. In Florida and Alabama, however, this null hypothesis cannot be rejected for the entire storm period.

Next, we examine the relationship between vulnerability and power failure intensity for the failure and recovery phases. In the failure phase in Georgia, the observed vulnerability-weighted resilience curve depart from the confidence region 97%, while for Florida and Alabama there is no departure, compared with critical values π*(0, t̅, 0.10, 0.10) of 55%, 92% and 85%. For the recovery phases, the observed vulnerability-weighted resilience curves depart from the confidence region 96% of the time in Georgia (compared with critical value π*(t̅, T, 0.10, 0.10) of 56%), 39% for Florida (compared with critical value π*(t̅, T, 0.10, 0.10) of 62%) and 0% of the time in Alabama (compared with critical value π*(t̅, T, 0.10, 0.10) of 89%).

Thus, only in Georgia we reject the null hypothesis for both phases. In Florida and Alabama, the null hypothesis of independence between vulnerability and impact of failures cannot be rejected for either of the two phases. Overall, these results remain consistent with the claim that more vulnerable communities were affected more severely throughout the time evolution of failure and recovery in Georgia but not in the other two states.

Scenario 2: Aggregated Spatiotemporal Variation

The second scenario, takes into account the aggregated storm path by deriving the null distribution cⱼ⁽⁰⁾ from the empirical distribution of SVI for counties impacted by the storm only (i.e., light distributions in FIGS. 11A-11C). A county is considered affected by the storm if and only if at least 5% of the customers served in that county experience outage at some point during the event assuming more than 100 customers are served at that moment in time. While this scenario still does not take dynamic behavior of the storm into account, it focuses on the population of customers in the affected counties. In other words, the null hypothesis conditions on the impact on more vulnerable counties in an aggregated fashion. Therefore, this scenario provides a better understanding about whether the power grid is more robust in less vulnerable communities, or the utility's recovery response is correlated with community characteristics by conditioning on the aggregated impact of the event on communities.

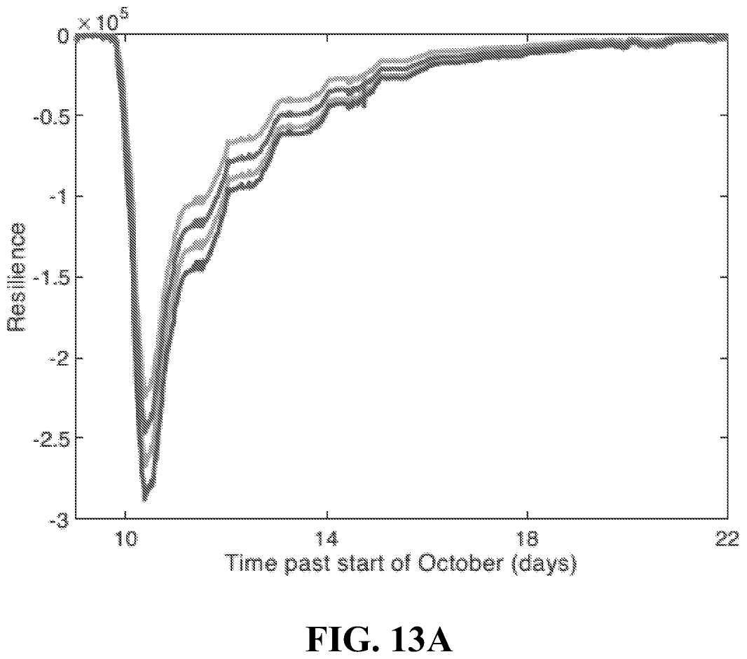

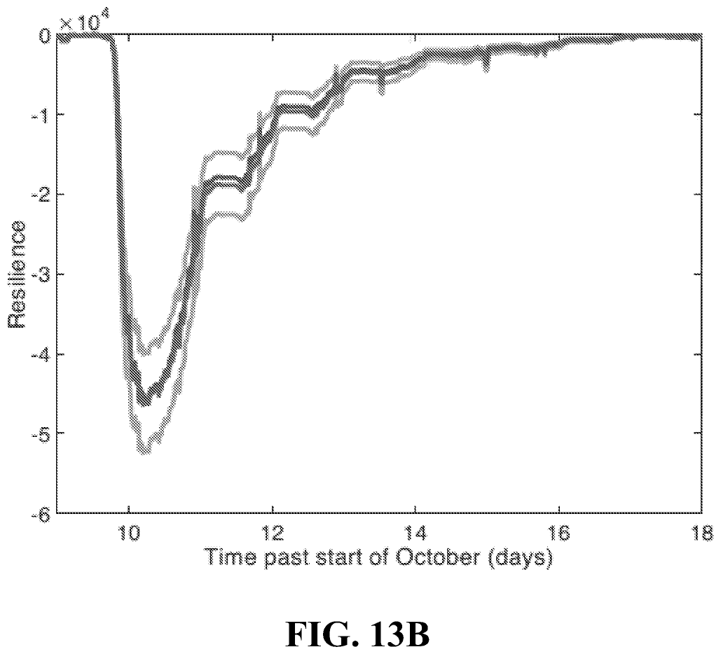

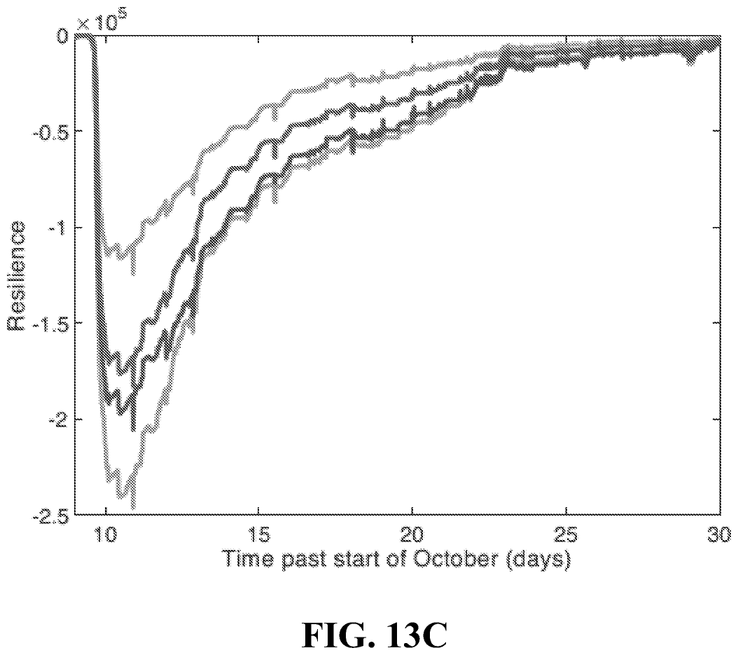

Next, we apply the randomization inference framework to this scheme. As demonstrated in FIGS. 13A-13C, Georgia still shows significant statistical dependence between vulnerability and recovery for most t. Throughout the entire storm duration, the resilience curve at Georgia departs from the confidence region 73% of the time, compared to a critical value of 54%. Further, for both the failure and recovery phase, the proportion of time outside the confidence region exceeds the critical values for Georgia. Specifically, the temporally-weighted resilience curve departs from the null hypothesis 94% and 72% of the time, compared with critical values of 53% and 56% for failure and recovery phase, respectively. We thus reject the null hypothesis that the recovery response is conditionally independent of the social vulnerability in Georgia in the entire event as well as failure and recovery phases. Even after conditioning on the affected counties, more vulnerable communities were affected more severely by the recovery response in Georgia.

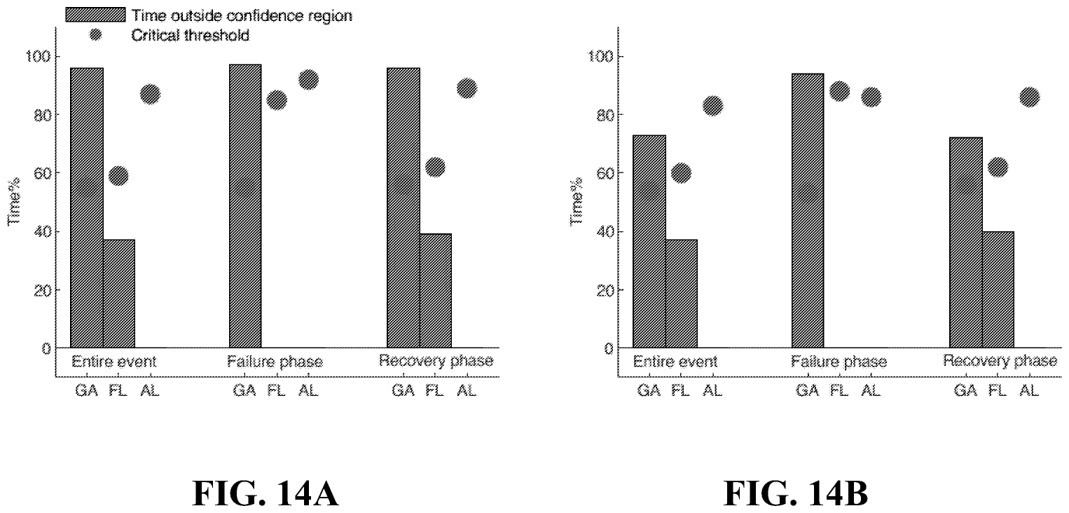

In contrast, in Alabama the vulnerability-weighted resilience curve falls within the confidence region for the entire storm and both sub-periods of failure and recovery phases. Thus, we cannot reject the null hypothesis of conditional independence between power failures and customer vulnerability. Finally, in Florida the vulnerability-weighted resilience curve departs from the confidence region only in recovery phase. In particular, for the entire storm and both sub-periods of failure and recovery phases, the proportions of time spent outside the confidence region are 37%, 0%, and 40%, respectively. These values are less than the corresponding critical values of 60%, 88%, and 62%. Thus, similar to Alabama, we cannot reject the null hypothesis of conditional independence between power failures and customer vulnerability. A comparison of the results for Alabama and Georgia is shown in FIGS. 14A, 14B for the entire storm, failure phase and recovery phase in scenario II.

Extension: Spatiotemporal Storm Variation

If data on specific failures and their corresponding failure time, recovery time and geo location become available, improvements can be made to our current framework. First, we can sample SVI for the null distribution of customers based on the actual failure causing outage instead of their impacted county. In other words, the granularity of the analysis goes from county level to failure level. Additionally, if latitude and longitude of failures are available, SVI can be defined over census tracts which are smaller spatial units. These aspects certainly improve the accuracy of the model validations.

Moreover, such data enable us to analyze the possibility that the relationship between vulnerability and power failures is the result of grid robustness or storm response routines (recovery performance of service providers) rather than the storm path. In order to accomplish this, cⱼ⁽⁰⁾ must be generated in a manner that conditions on the moment in the evolution of the storm that customer j experienced severe weather and on the regions within the state that experienced severe weather at that moment. Taken together, this approach controls for spatial and temporal independence between storm-caused severe weather and customer vulnerability.

Specifically, cⱼ⁽⁰⁾ is estimated in the following way: We begin by conditioning on the aggregate storm path by calculating the empirical distribution of SVI associated with observed device failures. Locations impacted more intensely by the severe weather will experience more device failures and, thus, will be oversampled relative to locations less impacted by the weather. Then, for each set of customers attached to a failed device, we sample from this empirical distribution in a manner that weights failures that occurred at more similar times more heavily than failures that occurred at more distant times (A similar weighting scheme could be applied spatially, but the existing spatial clustering of the storm track conditional on time makes this step redundant). In particular, for each failure i₁, the probability of a SVI from another failure i₂ being sampled is determined by how close in time those two failure it occur ([t_{f}(i₁)−t_{f}(i₂)]), where t_{f}(i₁) is the failure occurrence time for failure i₁. We define the sampling weights using a Gaussian kernel:

$$\frac{1}{{N}_{0}} {e}^{- \frac{{( {t}_{f} ( i ) - {t}_{f} ( j ) )}^{2}}{2 {σ}^{2}}} \qquad ( 29 )$$

where σ tunes the width of the kernel and N₀ is the normalization factor. As an example, σ can be defined as standard deviation of the failure occurrence times sd(t_{f}).

Note that, if we choose our kernel to be wide (large values of σ), the resulting null hypothesis curve will be almost sampling from the entire empirical distribution of the SVI scores associated with failed devices. On the other hand, a narrow kernel (small values of σ) will result in the null hypothesis weighted resilience curve Res₀(t) to approximate the actual weighted resilience curve Res(t), because for any failure i₁, we would be sampling the SVI from i₁ itself with high likelihood.

### Temporal Characteristics for Two Stages of Recovery

A recovery process from a weather event is the response of services to the occurrence of the failures (i.e., failure process). Both processes vary with time during a weather event. Recovery and failure occurrences are modeled as non-stationary spatial temporal random processes in our prior work. Thus, we use three temporal quantities to characterize the failure and recovery processes and their interactions: empirical failure rate F(t), recovery rate R (t) and the number of pending failures to recover Nₚ(t). The empirical failure rate F(t) is defined as the number of new failures occurred in a unit time duration. F (t) is estimated as the number of failures occurred over a window centered at time t, divided by the length of that window. Moving average technique is used to compute F(t) for every minute t. R (t), similar to F (t), is defined as the number of failures recovered in a window of time divided by the duration. Finally, the number of pending failures to repair Nₚ(t) is the count of failures that are yet to recover at time t. Nₚ(t) can be viewed as the interaction of F(t′) and R (t′) for t′<t. For example, if the system has been experiencing a relatively larger failure rate and smaller recovery rate for t′<t, Nₚ(t) will be large as more failures are waiting to recover. This is in contrast to the case of a smaller failure rate and larger recovery rate.

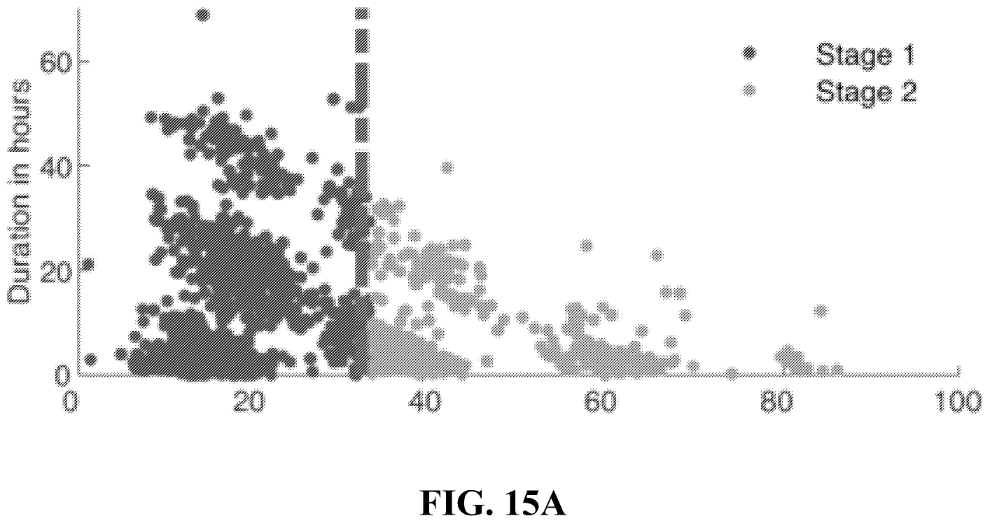

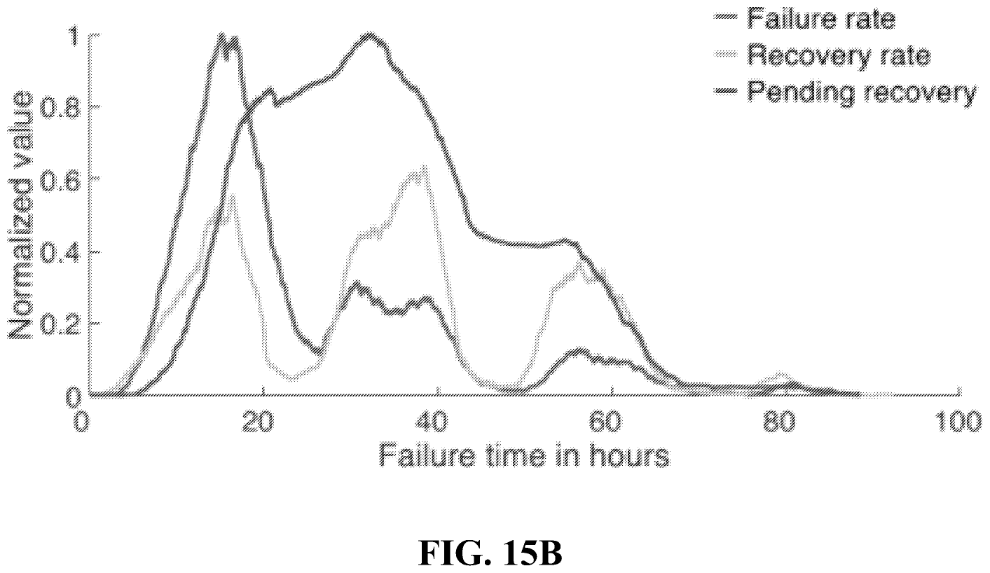

These three quantities provide insight on recovery as illustrated through a typical example of an extreme failure event in FIGS. 15A, 15B. At the beginning of a major storm, failures start to occur at a growing speed, which results in an increasing failure rate. As the failure rate continues to increase to its maximum, recovery process starts slowly and with a delay, often due to inclement weather and hazardous terrain conditions. This can be seen by comparing the peak value of the failure rate and recovery rate. It is the combination of a rising failure rate, delays in recovery and a relatively smaller recovery rate that result in having more and more pending repairs (i.e., an increasing Nₚ(t)). This persists until the failure rate starts to decrease and recovery begins to dominate.

As illustrated in FIGS. 15A, 15B, the severe and extreme failure events usually consist of one main peak for the failure rate F (t) and the number of pending failures to recover Nₚ(t), although there can be local peaks in those quantities. Hence, the maximum number of pending repairs max Nₚ(t) characterizes the two stages of a severe (or an extreme) failure event: Before Nₚ(t) reaches its peak value, the failure process dominates, where the failure rate often exceeds the recovery rate. Once passing the peak value max Nₚ(t), the recovery rate dominates until the end of the event. Hence, max Nₚ(t) provides a meaningful separation of a major failure event into two stages: Stage 1 for failure process domination and Stage 2 when recovery process takes over.

It should be noted that, in Stage 1, it is possible that there exists short periods of time when the two rates are close or the recovery rate is slightly larger than the failure rate. We find that those periods of time are insignificant and not affecting the overall behavior of the two stages.

In the case of moderate events, the overall distinction is less significant among the maximum values of the failure and recovery rates as well as the number of pending repairs. Moreover, due to less severity, the recovery rate is able to keep up more with the failure rate both in time and value compared to the major disruption events. Therefore, the temporal division of the events into two stages is only applied to the severe and extreme failure events. The following algorithm summarizes the procedure of defining the two stages.

Algorithm 5 Dividing a Severe or an Extreme Failure Event into Two Stages:
1. For each event, compute the number of pending failures for repair Nₚ(t) at every minute t.
2. Find tₘₐₓ, which corresponds to the time when Nₚ(t) reaches the maximum value, i.e., tₘₐₓ=argmax Nₚ(t).
3. Define stages 1 and 2 of the failure event as the spatiotemporal processes that occur before and after tₘₐₓ, respectively.

Using the above algorithm, we obtain the failures occurred at the two stages of a major event. The analyses for major events make use of only stage 1 failures.

We note that the majority of the failures that occurred during the recovery stage has relatively short interruption durations. Some of those interruptions on electricity supplies were indeed planned outages for necessitating repairs. Hence, the failures occurred at the first stage represent the majority induced by exogenous weather events. Additionally, the failure data at Stage 1 are considered to be reasonably accurate in interruption durations, since certain small failures were found during the recovery stage which might have occurred earlier (this of course can also occur to the small failures at Stage 1 to a lesser degree). Therefore, we use the data from the failure stage in our analysis.

To be specific, a total of 66% of failures in extreme events occurred in the failure stage while the remaining 34% at the recovery stage when restoration dominated. In particular, at the failure stage, there are 87% of large failures (each of which affected 100 or more customers); 75% of small-size failures except for one customer failures (each of which affected 2˜100 customers. For the failures where each affected one customer, 53% occurred in the failure state whereas the remaining were in the recovery stage. Therefore, given the significantly larger impact, both in terms of the number of customers affected and interruption durations, we use failures that occurred at the failure stage of the extreme and severe disruptions for our analysis.

The data we leave out in the recovery stage exclude a minute portion of failures with short durations. As such, our results here are more conservative in estimating the impact of the small failures than the prior work. While this may introduce a minute difference in actual percentages of small failures, the findings are consistent throughout our previous and current study: There were more (prolonged) small failures than the large ones, and those small failures affected a lot fewer customers but experienced much longer downtime durations.

### Unsupervised Learning for Recovery Behavior

We first estimate from data, the joint probability Pᵣ(XϵA, YϵB) between failure characteristics X and recovery speed Y (and the marginal distributions Pᵣ(XϵA) and Pᵣ(YϵB)). Here A and B are regions of X and Y values, respectively. The data set D available to this work is D={xᵢ^{(j)}, yᵢ^{(j)}} from n failure events, where (xᵢ^{(j)}, yᵢ^{(j)}) is the i-th sample from the j-th event (1≤j≤n) on failure characteristics X and recovery speed Y.

Failure characteristics X describe the impact on customers and physical structure of the distribution grid with a radial topology. The impact is represented by the number of customers affected by each failure. The structure of the grid is reflected by the activated protective devices (e.g., open substation breakers and reclosers) and damaged power components (e.g., transformers). The dependence is then quantified by f_{A,B}, which is the difference between the joint and product of the marginal probability distributions of the recovery speed Y, affected customers and outaged devices X; i.e. f_{A,B}=P(XϵA, YϵB)−P(XϵA)P(YϵB).

Then, a cluster specified by regions A∩B is obtained if f_{A,B} exceeds α threshold that is 5% of the maximum possible value (i.e., f_{A,B}≥0.05×max(f_{A,B})). And, the error bar of the estimation Err(f_{A,B}) is sufficiently small. The error bars are obtained through 5-fold cross validation for each event and averaged between the training and test data across events of a given type. The steps are given in Algorithm 3.

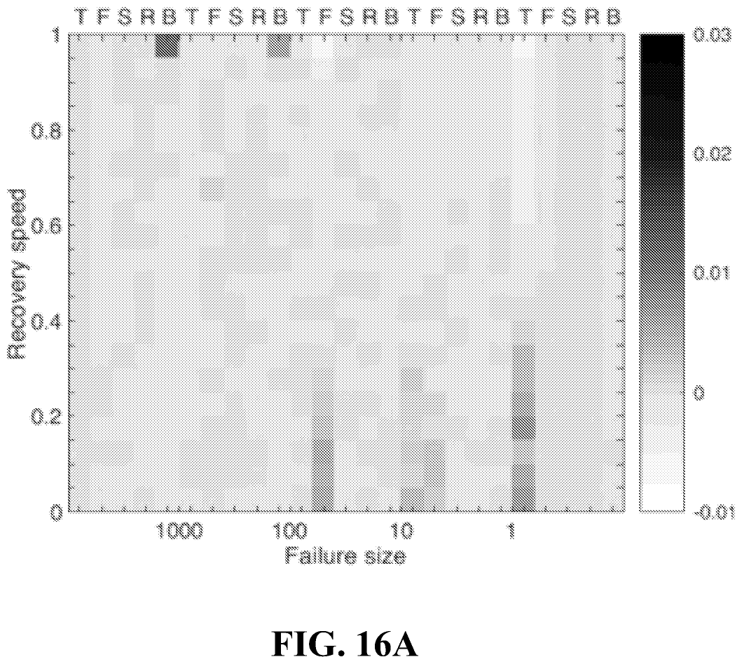

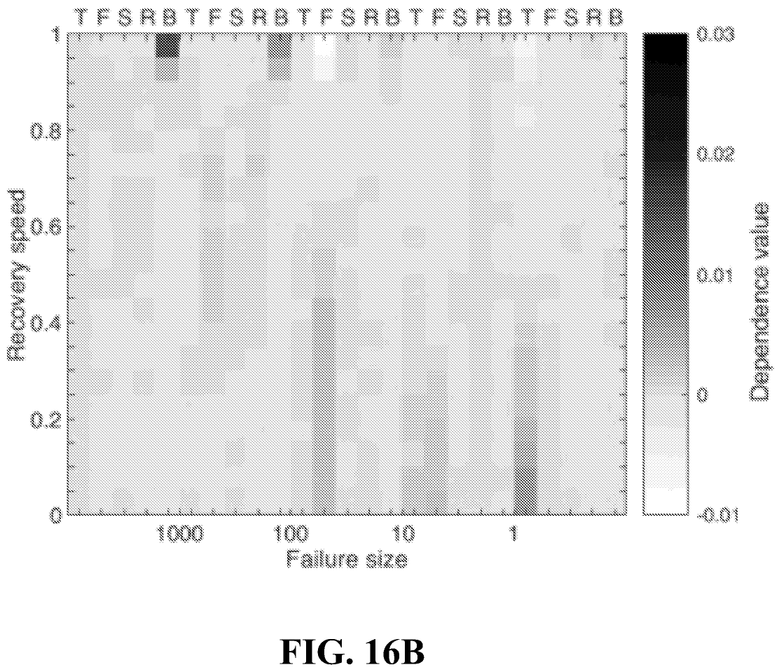

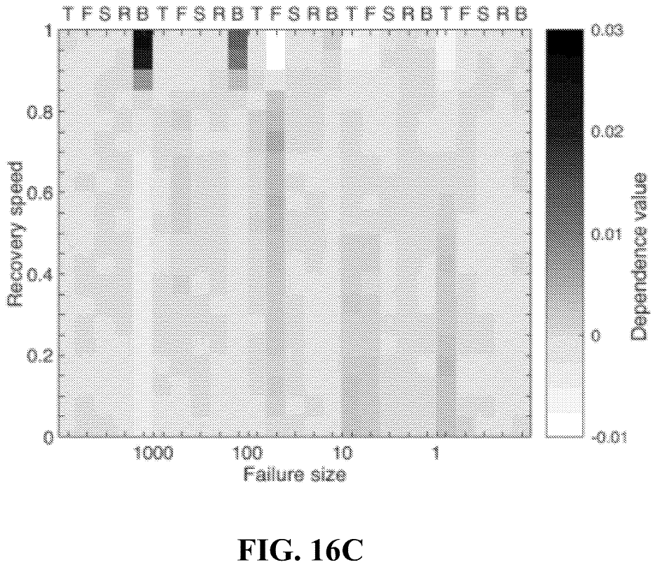

How recovery speed depends on grid structure and failure size is shown in FIGS. 16A-16C. It can be seen that given a failure size category, the recovery speed shows significant dependence to certain devices. For example, for large failures, each of which affects more than 100 customers, the recovery speed shows strong dependence only to station breakers. The dependence holds, between recovery speed and the following devices: fused discs when the number of affected customers (c_{f}) is 10<c_{f}<100, both fused discs and transformers when 2<c_{f}<10, and transformers for c_{f}=1 (i.e., there is only one affected customer per failure). Detailed numbers on the distribution of devices in the four clustered regions are shown in TABLE 3.

Therefore, the number of affected customers (i.e., failure size) represents most information in relating the feature variables to the recovery speed. As such, the failure size is used as the primary covariate in our analysis. The devices are used to provide insight on the role of distribution grid structure in recovery. These two variables provide the direct connection to the physical grid under study, however additional variables can be incorporated into this framework as they become available.

Focusing on the relationship between recovery speed and failure size as the only failure characteristic, the results are shown in FIGS. 5A-5F for winter and non-winter events and all three severities from moderate to extreme. It can be seen that there exist four clustered regions in the space spanned by the recovery speed and failure size in all results: prioritized large, non-prioritized large, remaining small and prolonged small. These regions show the same key characteristics across event types and severities while having minor differences in shapes.

Additionally however, it can be seen that some recovery speed ranks within the bottom 50˜100% do not show strong dependence to small failures while their speed is slower than prolonged small failures. A fifth region is thus defined for these failures called insignificant prolonged small failures. However, given the similar recovery behavior to prolonged small failures, we consider this group as part of prolonged small category in all the analysis and results.

It will be clear to a person skilled in the art that features described in relation to any of the embodiments described above can be applicable interchangeably between the different embodiments. The embodiments described above are examples to illustrate various features of the invention.

The reader's attention is directed to all papers and documents which are filed concurrently with or previous to this specification in connection with this application and which are open to public inspection with this specification, and the contents of all such papers and documents are incorporated herein by reference.

Numerous characteristics and advantages have been set forth in the foregoing description, together with details of structure and function. While the invention has been disclosed in several forms, it will be apparent to those skilled in the art that many modifications, additions, and deletions, especially in matters of shape, size, and arrangement of parts, can be made therein without departing from the spirit and scope of the invention and its equivalents as set forth in the following claims. Therefore, other modifications or embodiments as may be suggested by the teachings herein are particularly reserved as they fall within the breadth and scope of the claims here appended.

1. A method of prioritizing recovery from power failures across a utility service from among different failure severity characterizations of the power failures comprising:
unsupervised learning of non-stationary data related to prior power failure events.

2. The method of claim 1 further comprising:
developing a recovery scaling law for service resilience based upon analyses of the non-stationary data related to the prior power failure events.

3. The method of claim 1, wherein the failure severity characterizations are discrete categories based, at least in part, upon a number of customers affected by each power failure.

4. The method of claim 1, wherein at least a portion of power failures having a smaller failure severity characterization than power failures having a larger failure severity characterization are prioritized for recovery prior to recovery of one or more of the power failures having the larger failure severity characterizations.

5. A method basing resilient recovery services from large-scale data analytics on prior failure events comprising:
systematically studying prior recovery services under the prior failure events;
developing a recovery scaling law through unsupervised learning of the large-scale data; and
improving the performance of resilient recovery services from power failures based upon the studying and developing.

6. The method of claim 5, wherein improving comprises enhancing recovery of at least a portion of the power failures through distributed generation and storage.

7. The method of claim 5, wherein at least a portion of the power failures are induced by weather disruptions.

8. The method of claim 5, wherein the large-scale data comprises non-stationary data.

9. The method of claim 5, wherein one or more of the studied prior recovery services was based upon widely adopted prioritization policies favoring larger failure events, where prioritizing the recovery of power failures affecting a larger number of customers losing power was favored over prioritizing the recovery of power failures affecting a smaller number of customers losing power; and
wherein the studying finds that under those widely adopted prioritization policies favoring the larger failures events, recovery exhibits a scaling property where a majority of the customers recovers in a small fraction of total downtime.

10. The method of claim 9, wherein the majority of the customers is about 90% of the customers.

11. The method of claim 9, wherein the studying further finds that recovery degrades with the severity of the prior failure events.

12. The method of claim 11, wherein the larger failure events that cannot recover rapidly increase by 30% from lesser, moderate-to-extreme failure events.

13. The method of claim 9, wherein prolonged smaller failure events dominate the entirety of the studied prior recovery services.

14. A method of prioritizing the recovery of power failure events, the power failure events categorized by severity based upon the number of customers affected by each power failure event, comprising:
using data analytics for recovery priorities;
using granular and large-scale failure data from the distribution grid; and
developing a data driven recovery scaling law that characterizes how recovery speed scales with respect to the severity of power failure events.

15. A method of basing smart grid infrastructure on the method of prioritizing of claim 1.

16. A method to compare/analyze the effectiveness of enhancement procedures or investments to the prioritization of recovery of power failure events comprising:
testing recovery performance of a first state of a grid; and
testing recovery performance of a second state of a grid;
wherein the second state of the grid comprises grid enhancements or adoption of additional distributed energy resources over the first state of the grid.

17. The method of claim 16, wherein the grid enhancements or adoption of additional distributed energy resources are a result of using a method of prioritizing the recovery of power failure events, the power failure events categorized by severity based upon the number of customers affected by each power failure event, using data analytics for recovery priorities, using granular and large-scale failure data from the distribution grid comprising developing a data driven recovery scaling law that characterizes how recovery speed scales with respect to the severity of power failure events

18. A method of using a data-driven tool to make regulatory decisions, the data-driven tool comprising a data driven recovery scaling law that characterizes how recovery speed scales with respect to severity of power failure events.

19. The method of claim 1 further comprising:
developing a recovery scaling law for service resilience based upon analyses of the non-stationary data related to the prior power failure events;
wherein the failure severity characterizations are discrete categories based, at least in part, upon a number of customers affected by each power failure; and
wherein at least a portion of power failures having a smaller failure severity characterization than power failures having a larger failure severity characterization are prioritized for recovery prior to recovery of one or more of the power failures having the larger failure severity characterizations.

20. The method of claim 5, wherein the prior failure events have different severities;
wherein studying comprises studying prior recovery services under the different severities of failure impact;
wherein improving comprises enhancing recovery of a portion of large failures through distributed generation and storage;
wherein at least a portion of the failure events are induced by weather disruptions;
wherein the large-scale data comprises non-stationary data; and
wherein studying finds that under widely adopted prioritization policies favoring larger failures, recovery exhibits a scaling property where a majority of customers recovers in a small fraction of total downtime.

21. A method of basing smart grid infrastructure on the method of prioritizing of claim 5.
